(19) United States
(12) Patent Application Publication
(10) Pub. No.: US 2025/0349561 A1
(43) Pub. Date: Nov. 13, 2025

(54) MOLD RELEASE FILM AND METHOD FOR MANUFACTURING SEMICONDUCTOR PACKAGE

(71) Applicant: AGC Inc., Tokyo (JP)

(72) Inventors: Takatoshi YAOITA, Tokyo (JP); Masanobu ISSHIKI, Tokyo (JP); Masami SUZUKI, Tokyo (JP); Shotaro BEPPU, Tokyo (JP); Takayuki MOURI, Tokyo (JP)

(73) Assignee: AGC Inc., Tokyo (JP)

(21) Appl. No.: 19/276,077

(22) Filed: Jul. 22, 2025

Related U.S. Application Data
(63) Continuation of application No. PCT/JP2024/003041, filed on Jan. 31, 2024.

(30) Foreign Application Priority Data
Feb. 3, 2023 (JP) 2023-015583

(51) Int. Cl. H01L 21/56

(52) U.S. Cl. CPC H01L 21/566

(57) ABSTRACT

Provided is a mold release film including a mold release layer, an antistatic layer, and a substrate in this order, in which an average thickness of the mold release layer is more than 0.1 μm, and when unevenness of a surface of the mold release film on a mold release layer side is measured with a laser microscope and a surface angle distribution of an angle (θ) formed by a normal vector of the unevenness and a normal line of a main surface of the mold release film is determined, an existence fraction (Φ) in a range of 10° to 35° is 0.12 or more.

### CROSS-REFERENCE TO RELATED APPLICATIONS

This is a bypass continuation of International Application No. PCT/JP2024/003041 filed on Jan. 31, 2024, and claims priority from Japanese Patent Application No. 2023-015583 filed on Feb. 3, 2023, the entire content of which is incorporated herein by reference.

### TECHNICAL FIELD

The present invention relates to a mold release film and a method for manufacturing a semiconductor package.

### BACKGROUND ART

A semiconductor package includes a resin-encapsulation portion that protects a semiconductor element. A curable resin such as a thermosetting epoxy resin is widely used to form the resin-encapsulation portion.

As a method of encapsulating the semiconductor element, a so-called compression molding method and a transfer molding method are known in which a board on which a semiconductor element is mounted is disposed in a cavity of a mold, and the cavity is filled with a curable resin to form a resin-encapsulation portion. In these encapsulating methods, a mold release film is usually disposed on a cavity surface of the mold in order to prevent the resin-encapsulation portion from adhering to the mold. In such a case, a surface shape of the mold release film is transferred to a surface of the resin-encapsulation portion.

On a surface of an encapsulated semiconductor package, identification information such as a manufacturer name, a product name, and a lot number is marked by laser marking to ensure subsequent tracking. When visibility of a marking portion is poor, there may be a problem such as a manufacturer and a user being unable to identify a product.

In such a situation, for example, Patent Literature 1 proposes a mold release film having a surface state with a surface smoothness (Ra) of 0.1 μm to 0.5 μm and an average unevenness interval (RSm) of 90 μm to 125 μm. When this mold release film is used, a contrast between a non-marking portion and a marking portion increases, and visibility of the marking portion is excellent.

### CITATION LIST

### Patent Literature

Patent Literature 1: JP2014-179593A

### SUMMARY OF INVENTION

### Technical Problem

If there are scratches, dirt, or the like on a surface of the semiconductor package, there may be a problem in appearance quality. From a viewpoint of making such small scratches or the like less noticeable, the surface of the semiconductor package is made slightly rough and matte rather than mirror-finished. When the contrast between the non-marking portion and the marking portion is increased as in Patent Literature 1, scratches or the like on the non-marking portion tend to become more noticeable, deteriorating the appearance quality. The identification information may be erroneously read due to the scratches or the like.

In recent years, a semiconductor element has become narrower in line width, and dielectric breakdown of the semiconductor element is likely to occur due to electro-static discharge (ESD) caused by slight static electricity, which was not a problem before. When a semiconductor package is manufactured by encapsulating a semiconductor element using a mold release film, a curable resin is cured to form a resin-encapsulation portion, and then the mold release film is peeled off from the resin-encapsulation portion. It is also required to prevent ESD during this peeling.

The present disclosure provides a mold release film capable of forming a surface of a semiconductor package that has excellent antistatic properties and releasability from the semiconductor package and has excellent laser marking visibility, and a method for manufacturing a semiconductor package using the mold release film.

### Solution to Problem

Specific means for achieving the above object are as follows.

<1> A mold release film including a mold release layer, an antistatic layer, and a substrate in this order, in which
an average thickness of the mold release layer is more than 0.1 μm, and
when unevenness of a surface of the mold release film on a mold release layer side is measured with a laser microscope and a surface angle distribution of an angle (θ) formed by a normal vector of the unevenness and a normal line of a main surface of the mold release film is determined, an existence fraction (Φ) in a range of 10° to 35° is 0.12 or more.

<2> The mold release film according to <1>, in which an arithmetic average height Sa of at least one surface of the substrate is 0.9 μm or more.

<3> The mold release film according to <2>, in which an arithmetic average height Sa of a surface of the substrate on an antistatic layer side is 1.2 μm or more.

<4> The mold release film according to any one of <1> to <3>, in which a content ratio of particles in the mold release layer is 25 vol % or less.

<5> The mold release film according to any one of <1> to <4>, in which the substrate contains a fluororesin.

<6> The mold release film according to <5>, in which the fluororesin contains an ethylene-tetrafluoroethylene copolymer.

<7> The mold release film according to any one of <1> to <6>, in which the surface of the mold release film on the mold release layer side has a surface resistivity of 1×10⁷Ω/□ to 1×10¹¹Ω/□.

<8> The mold release film according to any one of <1> to <7>, which is to be disposed between a curable resin and a surface of a mold in manufacture of a semiconductor package.

<9> The mold release film according to <8>, in which the surface of the mold release film on the mold release layer side is to be in contact with the curable resin.

<10> A method for manufacturing a semiconductor package, the semiconductor package including a semiconductor element and a resin-encapsulation portion that encapsulates the semiconductor element and is formed of a curable resin, the method including:
disposing a board including the semiconductor element in a cavity of a mold;
disposing, on a cavity surface of the mold on which the board is not disposed, the mold release film according to any one of <1> to <9> that includes the mold release layer, the antistatic layer, and the substrate such that the surface on the mold release layer side faces a space in the cavity; and
filling the cavity with the curable resin and curing the curable resin in a state of being in contact with the mold release film to form the resin-encapsulation portion that encapsulates the semiconductor element.

### Advantageous Effects of Invention

According to the present disclosure, it is possible to provide a mold release film capable of forming a surface of a semiconductor package that has excellent antistatic properties and releasability from the semiconductor package and has excellent laser marking visibility, and a method for manufacturing a semiconductor package using the mold release film.

### BRIEF DESCRIPTION OF DRAWINGS

FIG. 1 is a diagram illustrating a surface angle distribution and an existence fraction (Φ) in a range of 100 to 35°.

FIG. 2 is a diagram illustrating an angle (θ) formed by a normal vector of unevenness on a surface of a mold release film and a normal line of a main surface of the mold release film.

FIG. 3 is a cross-sectional view schematically illustrating an outline of a compression molding method as an example of a method for manufacturing a semiconductor package of the present disclosure.

FIG. 4 is a cross-sectional view schematically illustrating the outline of the compression molding method as the example of the method for manufacturing the semiconductor package of the present disclosure.

FIG. 5 is a cross-sectional view schematically illustrating the outline of the compression molding method as the example of the method for manufacturing the semiconductor package of the present disclosure.

FIG. 6 is a cross-sectional view schematically illustrating an outline of a transfer molding method as an example of the method for manufacturing the semiconductor package of the present disclosure.

FIG. 7 is a cross-sectional view schematically illustrating the outline of the transfer molding method as the example of the method for manufacturing the semiconductor package of the present disclosure.

FIG. 8 is a cross-sectional view schematically illustrating the outline of the transfer molding method as the example of the method for manufacturing the semiconductor package of the present disclosure.

FIG. 9 is a cross-sectional view schematically illustrating the outline of the transfer molding method as the example of the method for manufacturing the semiconductor package of the present disclosure.

FIG. 10 is a cross-sectional view schematically illustrating the outline of the transfer molding method as the example of the method for manufacturing the semiconductor package of the present disclosure.

FIG. 11 is a cross-sectional view schematically illustrating the outline of the transfer molding method as the example of the method for manufacturing the semiconductor package of the present disclosure.

### DESCRIPTION OF EMBODIMENTS

Hereinafter, embodiments according to the present disclosure will be described in detail. However, the present disclosure is not limited to the following embodiments. In the following embodiments, constituent elements (including element steps and the like) are not essential unless otherwise specified. The same applies to numerical values and ranges thereof, which do not limit the present disclosure.

In the present disclosure, the term “step” includes not only a step that is independent of other steps, but also a step that cannot be clearly distinguished from other steps, as long as the purpose of the step is achieved.

In the present disclosure, a numerical range indicated by using “to” includes numerical values described before and after “to” as a minimum value and a maximum value, respectively.

In a numerical range described in stages in the present disclosure, an upper limit value or a lower limit value described in one numerical range may be replaced with an upper limit value or a lower limit value of another numerical range described in stages. In a numerical range described in the present disclosure, an upper limit value or a lower limit value of the numerical range may be replaced with values described in Examples.

In the present disclosure, each component may contain a plurality kinds of corresponding substances. When a plurality kinds of substances corresponding to each component are present in a composition, a content ratio or content of each component means a total content ratio or content of the plurality kinds of substances present in the composition unless otherwise specified.

In the present disclosure, a particle corresponding to each component may include plurality kinds of particles. When plurality kinds of particles corresponding to each component are present in a composition, a particle diameter of each component means a value of a mixture of the plurality kinds of particles present in the composition unless otherwise specified.

In the present disclosure, the term “layer” includes, when a region where the layer is present is observed, a case where the layer is formed over the entire region, as well as a case where the layer is formed over only a part of the region.

When the present disclosure is described with reference to the drawings, the present disclosure is not limited to the drawings. Sizes of members in the drawings are conceptual, and a relative relationship between the sizes of the members is not limited thereto.

The term “(meth)acrylate” is a generic term for acrylate and methacrylate.

The term “acrylic-based polymer” is a polymer having a unit based on (meth)acrylate. The unit based on (meth)acrylate contained in the acrylic-based polymer may be one type or two or more types. The acrylic-based polymer may further have a unit based on a monomer other than the unit based on (meth)acrylate.

In the present disclosure, a unit based on a monomer may be expressed by adding a unit to a monomer name, for example, as an ethylene unit.

In the present disclosure, the term “laser marking visibility” refers to recognizability in an automatic visualization inspection (AVI). In the AVI, light incident at a specific angle with respect to a horizontal plane of a surface of a semiconductor package is detected as a luminance by a detector located at 90°.

In the present disclosure, an arithmetic average height Sa is measured in accordance with ISO-25178-2: 2012. A laser microscope is used for the measurement, and an environmental temperature is 23° C. to 25° C.

### <Mold Release Film>

A mold release film of the present disclosure is a mold release film including a mold release layer, an antistatic layer, and a substrate in this order, in which an average thickness of the mold release layer is more than 0.1 μm, and when unevenness of a surface of the mold release film on a mold release layer side is measured with a laser microscope and a surface angle distribution of an angle (θ) formed by a normal vector of the unevenness and a normal line of a main surface of the mold release film is determined, an existence fraction (Φ) in a range of 10° to 35° is 0.12 or more.

A reason for being able to form a surface of a semiconductor package that has excellent antistatic properties and releasability from the semiconductor package and has excellent laser marking visibility by the above configuration is presumed as follows, but the present invention is not limited to the following presumption.

From a viewpoint of preventing ESD, when the antistatic layer is provided on the mold release film, the mold release layer is often further provided on the antistatic layer in order to improve releasability from an encapsulating resin. If the mold release layer is too thin, releasability from a resin-encapsulation portion tends to be insufficient.

The mold release film of the present disclosure includes the mold release layer, the antistatic layer, and the substrate in this order from a side in contact with a curable resin, and thus has excellent antistatic properties, and the average thickness of the mold release layer is more than 0.1 μm, and thus releasability is ensured.

In the mold release film of the present disclosure, when the unevenness of the surface on the mold release layer side (surface of the mold release film on a side where the mold release layer is present with respect to the substrate, hereinafter, also referred to as a “first surface”) is measured with the laser microscope and the surface angle distribution of the angle (θ) formed by the normal vector of the unevenness and the normal line of the main surface of the mold release film is determined, the existence fraction (Φ) in the range of 100 to 350 is 0.12 or more. When a mold release film is produced by forming an antistatic layer and a mold release layer on a substrate having an uneven surface by coating, an angle of unevenness of the surface changes before and after the coating. A coating liquid tends to accumulate in a concave portion of a board, and thus when each layer is formed on the substrate by the coating, the angle of the surface tends to be gentler in the concave portion than in a convex portion as the change before and after the coating. The visibility is affected by a surface shape of the entire uneven surface, and thus it is preferable that in the mold release film of the present disclosure produced by this manufacturing method, a surface roughness of the substrate and average thicknesses of the antistatic layer and the mold release layer are controlled to optimize a surface shape of the entire concave portion and convex portion, and as a result, the existence fraction (Φ) in the range of 100 to 350 is 0.12 or more to improve the laser marking visibility.

First, a method of determining the existence fraction (Φ) will be described.

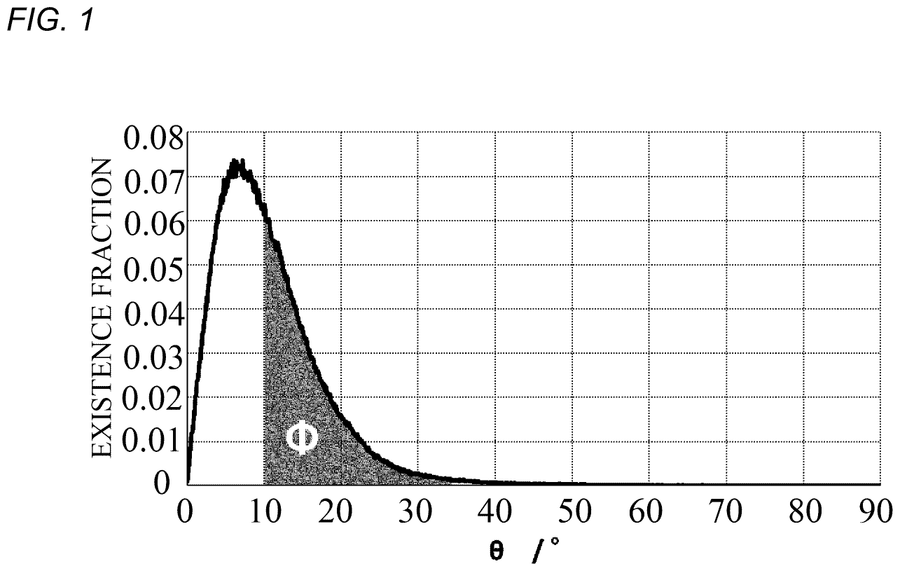

A surface shape of the mold release film is measured using the laser microscope in increments of 0.25 μm for both an X coordinate and a Y coordinate at an environmental temperature of 23° C. to 25° C. in accordance with ISO-25178-2: 2012. For the obtained data of the X coordinate, the Y coordinate, and a Z coordinate (height), a normal vector of the unevenness at each point is determined using a MATLAB (registered trademark) R2022b surfnorm function. The angle (θ) formed by the normal vector of the unevenness at each point and the normal line of the main surface of the mold release film is determined, and a histogram is generated in increments of 0.1° to determine the surface angle distribution. FIG. 1 shows an example of the surface angle distribution. In a graph of the surface angle distribution in FIG. 1, an area ratio of the range of the angle (θ) of 10° to 35° to a total area of a total angle of 0° to 90° is determined as the existence fraction (Φ) in the range of 100 to 35°.

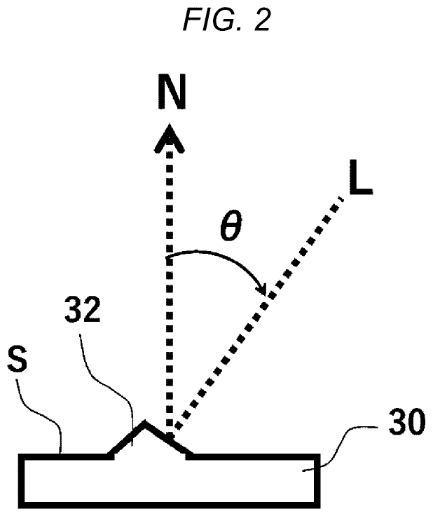

Here, the angle (θ) formed by the normal vector of the unevenness on the first surface of the mold release film and the normal line of the main surface of the mold release film will be described with reference to FIG. 2. As shown in FIG. 2, in a mold release film 30, an angle formed by a normal line N of a main surface S having an unevenness 32 and a normal vector L of the unevenness 32 is θ. The main surface S is a surface extending in a direction perpendicular to a thickness direction of the mold release film, and the normal line N of the main surface S can also be said to be the thickness direction of the mold release film.

Therefore, the existence fraction (Φ) in the range of 100 to 350 means a ratio of the angle of 10° to 35° to an angle of the normal vector of the unevenness of the surface of the mold release film with respect to the normal line of the main surface of the mold release film.

For example, when light is observed from the top of the mold release film, that is, from a normal direction of the main surface of the mold release film, light incident at an angle of 20° with respect to the normal line of the main surface of the mold release film is observed as light reflected by a surface having an angle (θ) of 10°. In addition, light incident at an angle of 70° with respect to the normal direction of the main surface of the mold release film is observed as light reflected by a surface having an angle (θ) of 35°.

Therefore, when the angle (θ) is 10° to 35°, light incident at an angle of 20° to 70° with respect to the normal direction of the main surface of the mold release film is reflected in the normal direction of the main surface of the mold release film, and the light is easily visually recognized from the top of the mold release film.

An uneven shape of the surface of the mold release film is transferred to the surface of the semiconductor package. On the surface of the semiconductor package, a shape obtained by inverting the uneven shape of the surface of the mold release film is formed, and an angle formed by the normal vector of the unevenness on the surface of the semiconductor package and a normal line of the horizontal plane of the surface of the semiconductor package is the same as an angle (θ) of a corresponding portion of the surface of the mold release film. Therefore, it is considered that visibility of light on the surface of the semiconductor package coincides with visibility of light on the surface of the mold release film.

Then, the present inventors have experimentally found that when the existence fraction (Φ) in the range of the angle (θ) of 10° to 35° in the mold release film is 0.12 or more, visibility of a print formed by laser marking on the surface of the semiconductor package is excellent when it is inspected with the AVI including the detector located at 90° with respect to the horizontal plane of the surface of the semiconductor package.

The existence fraction (Φ) in the range of 100 to 350 is 0.12 or more, and is preferably 0.14 or more, and more preferably 0.15 or more from a viewpoint of improving appearance quality that makes a resin flow trace (flow mark) on the surface of the semiconductor package and scratches on the surface of the package less noticeable while maintaining the laser marking visibility.

In addition, the existence fraction (Φ) in the range of 100 to 350 is preferably 0.66 or less, more preferably 0.65 or less, and still more preferably 0.64 or less from a viewpoint of further improving the laser marking visibility.

An example in which the mold release film of the present disclosure is used by being disposed between a curable resin and a surface of a mold in manufacture of the semiconductor package is given. The mold release film is preferably disposed such that the surface (first surface) of the mold release film on the mold release layer side is in contact with the curable resin. In the manufacture of the semiconductor package, a semiconductor element is disposed in the mold, and the semiconductor element is encapsulated with the curable resin to form a resin-encapsulation portion.

### (Substrate)

A material (including a composition) constituting the substrate is not particularly limited, and a known material such as a resin used for the mold release film can be applied. The resin used for the substrate preferably contains a resin having releasability from a viewpoint of excellent releasability of the mold release film from the mold after the encapsulation. The resin having releasability means a resin in which a layer formed by the resin alone has releasability.

Examples of the resin having releasability include a fluororesin, polymethylpentene, syndiotactic polystyrene, a polycycloolefin, a silicone rubber, a polyester elastomer, polyethylene terephthalate, polybutylene terephthalate, and a cast nylon. From viewpoints of the releasability from the mold, heat resistance at a mold temperature (for example, 180° C.) during the encapsulation, a strength to withstand a flow and a pressure of the curable resin, an elongation at a high temperature, and the like, a fluororesin, a polymethylpentene, syndiotactic polystyrene, a polycycloolefin, and the like are preferred, and from the viewpoint of excellent releasability, a fluororesin is particularly preferred. That is, the substrate preferably contains a fluororesin. These resins may be used alone or in combination of two or more types thereof.

A content ratio of a fluororesin in total resins contained in the substrate is preferably 80 mass % or more, more preferably 90 mass % or more, still more preferably 95 mass % or more, and particularly preferably 99 mass % or more, and may be 100 mass %.

The fluororesin is preferably a fluoroolefin-based polymer from viewpoints of excellent releasability and excellent heat resistance. The fluoroolefin-based polymer is a polymer having a unit based on a fluoroolefin. The fluoroolefin-based polymer may further have a unit other than the unit based on the fluoroolefin.

Examples of the fluoroolefin include tetrafluoroethylene (hereinafter, also referred to as “TFE”), vinyl fluoride, vinylidene fluoride, trifluoroethylene, hexafluoropropylene, and chlorotrifluoroethylene. The fluoroolefin may be used alone or in combination of two or more types thereof.

Examples of the fluoroolefin-based polymer include an ethylene-tetrafluoroethylene copolymer (ETFE), a tetrafluoroethylene-hexafluoropropylene copolymer (FEP), a tetrafluoroethylene-perfluoro(alkyl vinyl ether) copolymer (PFA), and a tetrafluoroethylene-hexafluoropropylene-vinylidene fluoride copolymer (THV). The fluoroolefin-based polymer may be used alone or in combination of two or more types thereof.

The fluoroolefin-based polymer is particularly preferably ETFE from a viewpoint of a large elongation at a high temperature. ETFE is a copolymer having a TFE unit and an ethylene unit (hereinafter, also referred to as an “E unit”). That is, the fluororesin contained in the substrate is preferably ETFE.

The ETFE may have a unit based on a third monomer other than the TFE unit and the E unit. The third monomer may be used alone or in combination of two or more types thereof. Examples of the third monomer include a monomer having a fluorine atom and a monomer having no fluorine atom.

Examples of the monomer having a fluorine atom include the following monomers (a1) to (a5).

Monomer (a1): fluoroolefins each having 2 or 3 carbon atoms.

Monomer (a2): fluoroalkylethylenes represented by X(CF₂)ₙCY=CH₂ (where X and Y each independently represent a hydrogen atom or a fluorine atom, and n is an integer of 2 to 8).

Monomer (a3): fluorovinylethers.

Monomer (a4): functional group-containing fluorovinylethers.

Monomer (a5): a fluorine-containing monomer having an alicyclic structure.

Examples of the monomer (a1) include fluoroethylenes (trifluoroethylene, vinylidene fluoride, vinyl fluoride, chlorotrifluoroethylene, and the like), and fluoropropylenes (hexafluoropropylene (hereinafter, also referred to as “HFP”), 2-hydropentafluoropropylene, and the like).

The monomer (a2) is preferably a monomer having n of 2 to 6, and particularly preferably a monomer having n of 2 to 4. A monomer whose X is a fluorine atom and Y is a hydrogen atom, that is, (perfluoroalkyl)ethylene is particularly preferred.

Specific examples of the monomer (a2) include the following compounds.
CF₃CF₂CH═CH₂,
CF₃CF₂CF₂CF₂CH═CH₂ (perfluorobutyl)ethylene, hereinafter, also referred to as “PFBE”),
CF₃CF₂CF₂CF₂CF═CH₂,
CF₂HCF₂CF₂CF═CH₂,
CF₂HCF₂CF₂CF₂CF═CH₂, and the like.

Specific examples of the monomer (a3) include the following compounds. Among the following, a monomer that is a diene is a monomer capable of undergoing cyclopolymerization.
CF₂═CFOCF₃,
CF₂═CFOCF₂CF₃,
CF₂═CFO(CF₂)₂CF₃ (perfluoro(propyl vinyl ether), hereafter also referred to as “PPVE”),
CF₂═CFOCF₂CF(CF₃)O(CF₂)₂CF₃,
CF₂═CFO(CF₂)₃O(CF₂)₂CF₃,
CF₂═CFO(CF₂CF(CF₃)O)₂(CF₂)₂CF₃,
CF₂═CFOCF₂CF(CF₃)O(CF₂)₂CF₃,
CF₂═CFOCF₂CF═CF₂,
CF₂═CFO(CF₂)₂CF═CF₂, and the like.

Specific examples of the monomer (a4) include the following compounds.
CF₂═CFO(CF₂)₃CO₂CH₃,
CF₂═CFOCF₂CF(CF₃)O(CF₂)₃CO₂CH₃,
CF₂═CFOCF₂CF(CF₃)O(CF₂)₂SO₂F, and the like.

Specific examples of the monomer (a5) include perfluoro(2,2-dimethyl-1,3-dioxole), 2,2,4-trifluoro-5-trifluoromethoxy-1,3-dioxole, and perfluoro(2-methylene-4-methyl-1,3-dioxolane).

Examples of the monomer having no fluorine atom include the following monomers (b1) to (b4).

Monomer (b1): olefins.

Monomer (b2): vinyl esters.

Monomer (b3): vinyl ethers.

Monomer (b4): an unsaturated acid anhydride.

Specific examples of the monomer (b1) include propylene and isobutene.

Specific examples of the monomer (b2) include vinyl acetate.

Specific examples of the monomer (b3) include ethyl vinyl ether, butyl vinyl ether, cyclohexyl vinyl ether, and hydroxybutyl vinyl ether.

Specific examples of the monomer (b4) include maleic anhydride, itaconic anhydride, citraconic anhydride, and 5-norbornene-2,3-dicarboxylic anhydride.

As the third monomer, the monomer (a2), HFP, PPVE, and vinyl acetate are preferred, HFP, PPVE, CF₃CF₂CH═CH₂, and PFBE are more preferred, and PFBE is still more preferred, from a viewpoint of easily adjusting crystallinity and from a viewpoint of excellent tensile strength and elongation at a high temperature (particularly, at about 180° C.).

In the ETFE, a molar ratio of the TFE unit to the E unit (TFE unit/E unit) is preferably 80/20 to 40/60, more preferably 70/30 to 45/55, and particularly preferably 65/35 to 50/50. When the TFE unit/E unit is within the above range, heat resistance and a mechanical strength of the ETFE are excellent.

A ratio of the unit based on the third monomer in the ETFE is preferably 0.01 mol % to 20 mol %, more preferably 0.10 mol % to 15 mol %, and particularly preferably 0.20 mol % to 10 mol %, with respect to a total (100 mol %) of all units constituting the ETFE. When the ratio of the unit based on the third monomer is within the above range, the heat resistance and the mechanical strength of the ETFE are excellent.

When the unit based on the third monomer includes a PFBE unit, a ratio of the PFBE unit is preferably 0.5 mol % to 4.0 mol %, more preferably 0.7 mol % to 3.6 mol %, and particularly preferably 1.0 mol % to 3.6 mol %, with respect to the total (100 mol %) of all units constituting the ETFE. When the ratio of the PFBE unit is within the above range, the tensile strength and elongation at a high temperature (particularly, at about 180° C.) are improved.

A melting point of the ETFE is preferably 190° C. or higher, more preferably 200° C. or higher, still more preferably 210° C. or higher, and particularly preferably 220° C. or higher.

An upper limit of the melting point of the ETFE is not particularly limited, and is, for example, 270° C.

When the melting point of the ETFE is within such a range, the mold release film is likely to have excellent tensile strength and elongation at a high temperature (particularly, at about 180° C.).

The term “melting point” means a temperature corresponding to a maximum value of a melting peak measured by differential scanning calorimetry (DSC).

A melt flow rate (MFR) of the ETFE is preferably 2 g/10 min to 40 g/10 min, more preferably 3 g/10 min to 30 g/10 min, and particularly preferably 5 g/10 min to 20 g/10 min.

When the MFR of the ETFE is within such a range, the mold release film is likely to have a large elongation at a high temperature and excellent followability to the mold.

The MFR of the ETFE is a value measured at a load of 49 N and 297° C. in accordance with ASTM D3159.

The substrate may further contain a component other than the resin.

Examples of the other component include a lubricant, an antioxidant, an antistatic agent, a plasticizer, and a mold release agent. A content ratio of the other component in the substrate is preferably 5 mass % or less, more preferably 1 mass % or less, still more preferably 0.5 mass % or less, and particularly preferably 0 mass % (not included), from a viewpoint of preventing staining of the mold.

An arithmetic average height Sa of at least one surface of the substrate is preferably 0.9 μm or more, more preferably 1.1 μm or more, and still more preferably 1.2 μm or more, from viewpoints of improving the appearance quality that makes the scratches on the surface of the semiconductor package obtained using the mold release film less noticeable and preventing wrinkles of the film on a surface of the mold in a encapsulating step of the semiconductor package. The arithmetic average height Sa of at least one surface of the substrate is preferably 2.7 μm or less, more preferably 2.6 μm or less, and still more preferably 2.5 μm or less, from the viewpoint of the laser marking visibility of the surface of the semiconductor package.

An arithmetic average height Sa of a surface of the substrate on a first surface side (antistatic layer side) is preferably 0.05 μm or more, more preferably 0.9 μm or more, still more preferably 1.2 μm or more, particularly preferably 1.4 μm or more, and extremely preferably 1.5 μm or more, from the viewpoint of improving the laser marking visibility and the appearance quality that makes the resin flow trace (flow mark) on the surface of the semiconductor package and the scratches on the surface of the package less noticeable.

The arithmetic average height Sa of the surface of the substrate on the first surface side is preferably 2.7 μm or less, more preferably 2.6 μm or less, and still more preferably 2.5 μm or less, from the viewpoint of the laser marking visibility.

In addition, from the viewpoints of preventing the wrinkles of the film on the surface of the mold in the encapsulating step of the semiconductor package and the releasability from the mold, an arithmetic average height Sa of a surface of the substrate of the mold release film on a surface (surface of the mold release film on a side where the substrate is present with respect to the mold release layer, hereinafter, also referred to as a “second surface”) side on the mold release layer side is preferably 0.03 μm or more, more preferably 0.05 μm or more, and still more preferably 0.1 μm or more.

The arithmetic average height Sa of the surface of the substrate on the second surface side is preferably 0.9 μm or more, more preferably 1.2 μm or more, still more preferably 1.3 μm or more, and particularly preferably 1.5 μm or more, from the viewpoint of preventing the wrinkles of the film on the surface of the mold in the encapsulating step of the semiconductor package. The arithmetic average height Sa of the surface of the substrate on the second surface side is preferably 2.7 μm or less, more preferably 2.6 μm or less, and still more preferably 2.5 μm or less, from the viewpoint of the laser marking visibility of the surface of the semiconductor package. When the arithmetic average height Sa of the surface of the substrate on the second surface side is equal to or less than the above upper limit value, a shape of the surface of the substrate on the second surface side is less likely to affect the surface of the semiconductor package.

The surface of the substrate on the second surface side may have an arithmetic average height Sa of less than 0.03 μm or 0.02 μm or less, or may be a mirror surface.

The arithmetic average height Sa of the surface of the substrate may be measured after removing the mold release layer, the antistatic layer, and other layers from the mold release film using methyl ethyl ketone.

In the substrate, a shape of a surface having an arithmetic average height Sa of 0.9 μm or more may be a shape in which at least one of a plurality of convex portions and concave portions are randomly distributed, or may be a shape in which at least one of a plurality of convex portions and concave portions are regularly arranged. Shapes of the plurality of convex portions may be the same or different. Sizes of the plurality of convex portions may be the same or different. Sizes of the plurality of concave portions may be the same or different.

Examples of the convex portion include a long convex part extending on the surface of the mold release film and scattered protrusions, and examples of the concave portion include a long groove extending on the surface of the mold release film and scattered holes.

Examples of a shape of the convex part or the groove include a linear shape, a curved shape, and a bent shape. The surface of the mold release film may have a striped pattern in which a plurality of convex parts or grooves are parallel to each other. Examples of a cross-sectional shape of the convex part or the groove in a direction orthogonal to a longitudinal direction include a polygon such as a triangle (V shape) and a semicircle.

Examples of a shape of the protrusion or the hole include a polygonal pyramid such as a triangular pyramid, a quadrangular pyramid, and a hexagonal pyramid, a cone, a hemisphere, a polyhedron, and various other irregular shapes.

A method for manufacturing a substrate having the surface with the arithmetic average height Sa of 0.9 μm or more is not particularly limited, and a known manufacturing method can be used. Examples of the method include a method of transferring unevenness of an original mold to a surface of a resin film by thermal processing, and from a viewpoint of productivity, the following methods (i) and (ii) and the like are preferred, and the method (ii) is particularly preferred.

(i) A method of passing a resin film between two rolls and continuously transferring unevenness formed on a surface of the roll to the resin film.

(ii) A method of passing a resin pushed from a die of an extruder between two rolls, forming the resin into a film shape, and continuously transferring unevenness formed on a surface of the roll to a surface of the resin having the film shape.

By using one of the two rolls as a roll having unevenness on a surface (hereinafter, also referred to as a mold roll) and the other as a roll having no unevenness, a substrate having unevenness on one side is manufactured. By using both of the two rolls as mold rolls, a substrate having unevenness on both surfaces is manufactured. One of the two rolls usually has a function of pressurizing the resin film and is called a pressing roll. When a roll having no unevenness on a surface is used, the roll having no unevenness is usually a cooling roll, and when both of the two rolls are mold rolls, one of the rolls is a cooling roll. The roll having no unevenness on the surface also means a roll having a surface capable of forming a substantially smooth surface.

The unevenness of the surface of the mold roll has a shape obtained by inverting a specific unevenness of the substrate, and has the same shape as unevenness to be formed on the surface of the resin-encapsulation portion of the semiconductor package.

Examples of a method for forming the unevenness on the surface of the mold roll include cutting and etching.

In a case of a rubber-wrapped roll, a mold roll having unevenness on a surface can be obtained by blending particles into a rubber sheet wound on a surface. In this case, a depth direction of a roughness, that is, Sa can be adjusted by a size of the particles blended in the rubber sheet. In a case of a resin-wrapped roll, Sa can be adjusted in the same manner.

In the methods (i) and (ii), the arithmetic average height Sa of the surface of the substrate can be adjusted by adjusting a processing speed, a melt flow rate (MFR) of a substrate resin, a pressure of the roll, a distance between the die and the roll, and the like, in addition to the unevenness of the surface of the roll.

An average thickness of the substrate is preferably 35 μm to 100 μm, and more preferably 35 μm to 75 μm. When a thickness of the substrate is 35 μm or more, the mold release film is likely to have excellent releasability. When the thickness of the substrate is 75 μm or less, the mold release film can be easily deformed and has excellent mold followability. When the thickness of the substrate is 100 μm or less, handling of the mold release film (for example, roll-to-roll handling) is easy, and wrinkles are less likely to occur when the mold release film is placed to cover a cavity of the mold while being stretched.

The average thickness of the substrate is measured in accordance with ISO 4591:1992 (JIS K7130:1999, B1 method, a method for measuring a thickness of a sample taken from a plastic film or sheet by a mass method). At this time, the average thickness of the substrate may be measured after removing the mold release layer, the antistatic layer, and the other layers from the mold release film using methyl ethyl ketone.

### (Antistatic Layer)

A material of the antistatic layer is not particularly limited as long as the antistatic layer has an antistatic function. The antistatic layer preferably contains an antistatic agent. Examples of the antistatic agent include an ionic liquid, a conductive polymer, a metal ion-conducting salt, and a conductive metal oxide.

The conductive polymer is a polymer in which electrons move and diffuse along a skeleton of the polymer (polymer skeleton). Examples of the conductive polymer include a polyaniline-based polymer, a polyacetylene-based polymer, a polyparaphenylene-based polymer, a polypyrrole-based polymer, a polythiophene-based polymer, and a polyvinylcarbazole-based polymer.

Examples of the metal ion-conducting salt include a lithium salt compound.

Examples of the conductive metal oxide include tin oxide, tin-doped indium oxide, antimony-doped tin oxide, phosphorus-doped tin oxide, zinc antimonate, and antimony oxide.

The antistatic layer preferably contains a resin binder. When the antistatic layer contains the resin binder and the antistatic agent, the antistatic agent is preferably dispersed in the resin binder.

The resin binder preferably has heat resistance to withstand heat (for example, 180° C.) in the encapsulating step. Examples thereof include an acrylic resin, a silicone resin, a urethane resin, a polyester resin, a polyamide resin, a vinyl acetate resin, an ethylene-vinyl acetate copolymer, an ethylene-vinyl alcohol copolymer, a chlorotrifluoroethylene-vinyl alcohol copolymer, and a tetrafluoroethylene-vinyl alcohol copolymer.

The resin binder may be crosslinked. When the resin binder is crosslinked, the heat resistance is excellent as compared with a case where the resin binder is not crosslinked.

Examples of such a resin binder include a carboxy group-containing (meth)acrylic polymer and a hydroxy group-containing acrylic polymer. Examples of the crosslinking agent include a polyfunctional aziridine compound and a polyfunctional epoxy compound in a case of a carboxy group-containing acrylic polymer, and a polyfunctional isocyanate compound in a case of a hydroxy group-containing acrylic polymer.

A surface resistivity of the antistatic layer is preferably 1×10¹⁰Ω/□ or less, and more preferably 1×10⁹Ω/□ or less. A lower limit value of the surface resistivity of the antistatic layer is not particularly limited, and may be 1×10⁷Ω/□ or more.

A content of the antistatic agent in the antistatic layer is appropriately set such that the surface resistivity of the antistatic layer is within the above range.

The average thickness of the antistatic layer is preferably 0.05 μm to 3 μm and more preferably 0.05 μm to 2 μm from a viewpoint of reducing a surface resistivity of the first surface of the mold release film while maintaining the releasability.

A method for measuring the average thickness of the antistatic layer and the average thickness of the mold release layer to be described later is not particularly limited.

For example, the average thickness of the antistatic layer and the average thickness of the mold release layer to be described later may be determined by removing the mold release layer and the antistatic layer from the mold release film using methyl ethyl ketone, measuring a mass before and after the removal of each layer, and using a reduced mass and a density of each layer.

The average thickness of the antistatic layer and the average thickness of the mold release layer to be described later may be determined by observing a cross section of the mold release film using a focused ion beam scanning electron microscope (FIB-SEM). In the FIB-SEM, based on a difference in a contrast between the layers, a boundary between the layers can be determined, and a thickness of each layer can be measured. Such measurement is performed at 30 randomly selected locations, or at least 30 locations between the concave portion and the convex portion when surface unevenness is observed, and measurement results are averaged to determine the average thickness of each layer.

When there is no difference in a contrast between the antistatic layer and the mold release layer at the time of observing the cross section by using the FIB-SEM and it is difficult to distinguish the boundary of the layers, a scanning transmission electron microscope (STEM-EDX) can be used to distinguish the boundary of the layers based on the presence or absence of characteristic elements in the antistatic layer (in particular, the antistatic agent contained in the antistatic layer) and the mold release layer.

A method for forming the antistatic layer is not particularly limited, and a method in which an antistatic layer composition is applied to one surface of a substrate and dried is preferred. As a coating method, various known wet coating methods can be used, and examples thereof include a gravure coating method, a die coating method, and a bar coating method. A temperature and a time for drying are appropriately adjusted depending on a type, a content, and the like of a liquid medium.

The antistatic layer composition may contain other components in addition to the antistatic agent. Examples of the other components include liquid media such as solvents and water. A solid content of the antistatic layer composition is appropriately adjusted in view of coating property.

Before applying the antistatic layer composition, the surface of the substrate is preferably subjected to a corona treatment from a viewpoint of enhancing wettability. The corona treatment is preferably performed such that a wetting tension based on IS08296: 1987 (JIS K6768: 1999) is 40 mN/m or more.

### (Mold Release Layer)

A material of the mold release layer is not limited as long as the mold release layer is a layer having releasability. The mold release layer may or may not have adhesiveness. The mold release layer preferably contains a reaction cured product of a hydroxy group-containing acrylic-based polymer and a polyfunctional isocyanate compound.

A hydroxy group in the hydroxy group-containing acrylic-based polymer is a crosslinking functional group that reacts with an isocyanate group in the polyfunctional isocyanate compound.

A hydroxyl value of the hydroxy group-containing acrylic-based polymer is preferably 1 mgKOH/g to 100 mgKOH/g, and particularly preferably 29 mgKOH/g to 100 mgKOH/g.

The hydroxyl value is measured by a method defined in JIS K0070:1992.

The hydroxy group-containing acrylic-based polymer may or may not have a carboxy group. Similar to the hydroxy group, the carboxy group is a crosslinking functional group that reacts with the isocyanate group in the polyfunctional isocyanate compound.

An acid value of the hydroxy group-containing acrylic-based polymer is preferably 0 mgKOH/g to 100 mgKOH/g, and particularly preferably 0 mgKOH/g to 30 mgKOH/g.

Similar to the hydroxyl value, the acid value is measured by the method defined in JIS K0070:1992.

A crosslinking functional group equivalent of the hydroxy group-containing acrylic-based polymer (total equivalent of the hydroxy group and the carboxy group) is 2,000 g/mol or less, preferably 500 g/mol to 2,000 g/mol, and particularly preferably 600 g/mol to 1,000 g/mol. The “total equivalent of the hydroxy group and the carboxy group” means a mass per 1 mol of a total of the hydroxy group and the carboxy group in the hydroxy group-containing acrylic-based polymer.

The crosslinking functional group equivalent corresponds to a molecular weight between crosslinking points, and is a physical property value that governs an elastic modulus after crosslinking (elastic modulus of the reaction cured product). When the crosslinking functional group equivalent is 2,000 g/mol or less, the elastic modulus of the reaction cured product is sufficiently high, and the releasability of the mold release layer from the resin-encapsulation portion and peelability from a semiconductor chip, a source electrode, or seal glass are excellent. When the crosslinking functional group equivalent is 2,000 g/mol or less, migration (adhesive residue) to the resin-encapsulation portion is prevented.

A mass average molecular weight (Mw) of the hydroxy group-containing acrylic-based polymer is preferably 100,000 to 1,200,000, more preferably 200,000 to 1,000,000, and particularly preferably 200,000 to 700,000. When the mass average molecular weight is 100,000 or more, the releasability from the resin-encapsulation portion and re-peelability from the semiconductor chip, the source electrode, or the seal glass are more excellent. When the mass average molecular weight is 1,200,000 or less, adhesion to the semiconductor chip, the source electrode, or the seal glass is more excellent.

The mass average molecular weight of the hydroxy group-containing acrylic-based polymer is a value in terms of polystyrene, which is obtained by measurement by gel permeation chromatography using a calibration curve prepared using a standard polystyrene sample having a known molecular weight.

A glass transition temperature (Tg) of the hydroxy group-containing acrylic-based polymer is preferably 20° C. or lower, and particularly preferably 0° C. or lower. When the Tg is equal to or less than an upper limit value of the above range, the mold release layer exhibits sufficient flexibility even at low temperatures and is easily peeled off from the substrate. The lower limit value of the Tg is not particularly limited, and the Tg is preferably −60° C. or higher in the above molecular weight range.

In the present disclosure, the Tg means a midpoint glass transition temperature measured by differential scanning calorimetry (DSC).

The polyfunctional isocyanate compound is a compound having 2 or more isocyanate groups, and is preferably a compound having 3 to 10 isocyanate groups.

Examples of the polyfunctional isocyanate compound include hexamethylene diisocyanate (HDI), tolylene diisocyanate (TDI), diphenylmethane diisocyanate (MDI), naphthalene diisocyanate (NDI), tolidine diisocyanate (TODI), isophorone diisocyanate (IPDI), xylylene diisocyanate (XDI), triphenylmethane triisocyanate, and tris(isocyanatophenyl)thiophosphate. Examples thereof include isocyanurates (trimers) and biurets of the polyfunctional isocyanate compounds, and adducts of the polyfunctional isocyanate compounds and polyol compounds.

The polyfunctional isocyanate compound preferably has an isocyanurate ring from a viewpoint that the reaction cured product (mold release layer) exhibits a high elastic modulus due to flatness of the ring structure.

Examples of the polyfunctional isocyanate compound having an isocyanurate ring include an isocyanurate of HDI (isocyanurate type HDI), an isocyanurate of TDI (isocyanurate type TDI), and an isocyanurate of MDI (isocyanurate type MDI).

The mold release layer may contain other components. Examples of the other components include a crosslinking catalyst (amines, a metal compound, an acid, and the like), a reinforcing filler, a coloring dye, a pigment, and an antistatic agent.

As the antistatic agent, those listed for the antistatic layer may be used.

When the polyfunctional isocyanate compound is used as the crosslinking agent, the crosslinking catalyst may be any substance that functions as a catalyst for a reaction (urethanization reaction) between the hydroxy group-containing acrylic-based copolymer and the crosslinking agent, and a general urethanization reaction catalyst can be used, and examples of the crosslinking catalyst include an amine-based compound such as a tertiary amine, and an organometallic compound such as an organotin compound, an organolead compound, and an organozinc compound. Examples of the tertiary amine include a trialkylamine, a N,N,N′,N′-tetraalkyldiamine, a N,N-dialkylamino alcohol, triethylenediamine, a morpholine derivative, and a piperazine derivative. Examples of the organotin compound include a dialkyltin oxide, a dialkyltin fatty acid salt, and a stannous fatty acid salt.

The crosslinking catalyst is preferably an organotin compound, and particularly preferably dioctyltin oxide, dioctyltin dilaurate, dibutyltin laurate, or dibutyltin dilaurate. A dialkylacetylacetonetin complex catalyst, which is synthesized by reacting a dialkyltin ester and acetylacetone in a solvent and has a structure in which two molecules of acetylacetone are coordinated to one atom of dialkyltin, can be used.

An amount of the crosslinking catalyst to be used is preferably 0.01 parts by mass to 0.5 parts by mass with respect to 100 parts by mass of the hydroxy group-containing acrylic-based polymer.

The mold release layer may contain particles. The existence fraction (Φ) in the range of 10° to 35° on the first surface of the mold release film may be adjusted by the particles. In addition, the existence fraction (Φ) in the range of 100 to 350 on the first surface of the mold release film may be adjusted by using a substrate having an uneven structure on a surface and further containing particles in the mold release layer. When the substrate having the uneven structure on the surface is used, the mold release layer may not contain particles.

A material of the particles contained in the mold release layer is not particularly limited, and may be, for example, organic particles or inorganic particles.

Examples of the organic particles include acrylic resin particles, polyolefin resin particles, polystyrene resin particles, polyacrylonitrile resin particles, and silicone resin particles.

Examples of the inorganic particles include silica particles and alumina particles.

An average particle diameter of the particles is preferably 2.0 μm or more, more preferably 2.5 μm or more, and still more preferably 3.0 μm or more. In such a case, the resin flow trace (flow mark) of the resin-encapsulation portion to be formed can be made less noticeable.

In addition, the average particle diameter of the particles is preferably 10 μm or less, more preferably 7.5 μm or less, and still more preferably 5 μm or less. In such a case, it is easy to prevent the particles from detaching from the mold release layer.

When the mold release layer contains the particles, a content ratio of the particles in the mold release layer is preferably 3.0 vol % or more, more preferably 3.9 vol % or more, and still more preferably 5.0 vol % or more, from a viewpoint of making the resin flow trace (flow mark) of the resin-encapsulation portion to be formed less noticeable. The content ratio of the particles in the mold release layer is preferably 25 vol % or less, more preferably 20 vol % or less, and still more preferably 16.5 vol % or less, from a viewpoint of easily preventing the particles from detaching from the mold release layer.

When the substrate having the uneven structure on the surface is used, the content ratio of the particles in the mold release layer is preferably 16.5 vol % or less, more preferably 10 vol % or less, and still more preferably 4.9 vol % or less, and may be 0 vol %, that is, no particles are contained, from the viewpoint of easily preventing the particles from detaching from the mold release layer.

The content ratio of the particles can be calculated as a ratio of resin particles per unit volume by, for example, observing a cross section of the mold release layer with a scanning electron microscope (SEM). Specifically, the content ratio can be calculated by the following method.

First, a cross section of a target mold release layer is observed by SEM, and the number and particle diameter of resin particles contained in any area (hereinafter, also referred to as a “target area”) in the cross section are measured. Further, any volume (hereinafter, also referred to as a “target volume”) is set based on the above target area, and the number of resin particles contained in the target volume is calculated. Further, a volume per a resin particle is calculated based on the particle diameter of the resin particles. Then, a total volume of the resin particles contained in the target volume is calculated based on the calculated number of resin particles and volume per a resin particle, and the total volume of the resin particles is divided by the target volume to calculate a volume content ratio of the resin particles contained in the target mold release layer.

The average thickness of the mold release layer is more than 0.1 μm, preferably 0.15 μm or more, more preferably 0.17 μm or more, and still more preferably 0.2 μm or more, from the viewpoint of the releasability of the mold release film. Since the thickness of the mold release layer is more than 0.1 μm, the releasability is ensured.

The thickness of the mold release layer is preferably 2.3 μm or less, more preferably 2.2 μm or less, and still more preferably 2.1 μm or less, from a viewpoint of antistatic properties of the mold release film. When the thickness of the mold release layer is 2.3 μm or less, the antistatic property is more excellent.

As a method for forming the mold release layer, a method is preferred in which a mold release layer composition containing each component of the mold release layer and a liquid medium is applied onto the antistatic layer and dried. As a coating method, various known wet coating methods can be used, and examples thereof include a gravure coating method, a die coating method, and abar coating method. Atemperature and a time for drying are appropriately adjusted depending on a type, a content, and the like of the liquid medium.

### (Other Layers)

The mold release film may include other layers. The other layers may be provided between a substrate layer and the antistatic layer or between the antistatic layer and the mold release layer, may be provided on a side of the substrate layer opposite to the antistatic layer, or may be provided on a side of the mold release layer opposite to the antistatic layer. For example, the other layers may be the first surface of the mold release film.

Examples of the other layers include a gas barrier layer and a coloring layer. These layers may be used alone or in combination of two or more types thereof. An average thickness of each of the other layers is preferably 0.05 μm to 3 μm, and more preferably 0.05 μm to 2 μm.

### (Various Physical Properties of Mold Release Film)

An arithmetic average height Sa of the first surface of the mold release film is preferably 1.0 μm or more, and more preferably 1.1 μm or more. In such a case, the resin flow trace (flow mark) of the resin-encapsulation portion to be formed is less noticeable, which is preferred.

When the mold release layer does not contain the particles, the arithmetic average height Sa of the first surface of the mold release film is preferably 2.3 μm or less, more preferably 2.2 μm or less, and still more preferably 2.1 μm or less. In such a case, the laser marking visibility of the surface of the semiconductor package formed using the mold release film is more excellent.

When the mold release layer contains the particles, the arithmetic average height Sa of the first surface of the mold release film is preferably 3.0 μm or less, more preferably 2.9 μm or less, and still more preferably 2.7 μm or less. In such a case, the laser marking visibility is more excellent.

A surface resistivity of the first surface of the mold release film is preferably 1×10¹¹Ω/□ or less, and more preferably 2×10¹⁰Ω/□ or less. In such a case, it is possible to effectively prevent breakage of the semiconductor chip due to discharge at the time of peeling. A lower limit value of the surface resistivity of the first surface of the mold release film is not particularly limited, and may be 1×10⁷Ω/□ or more.

The surface resistivity is measured in accordance with IEC 60093: double ring electrode method.

A static voltage of the first surface of the mold release film is preferably |0 to 50| V, more preferably 10 to 301 V, and still more preferably 10 to 251 V. The static voltage is measured by a surface electrometer.

### <Method for Manufacturing Semiconductor Package>

A method for manufacturing the semiconductor package of the present disclosure is a method for manufacturing a semiconductor package, the semiconductor package including a semiconductor element and a resin-encapsulation portion that encapsulates the semiconductor element and is formed of a curable resin, the method including: disposing a board including the semiconductor element in a cavity of a mold; disposing, on a cavity surface of the mold on which the board is not disposed, the mold release film of the present disclosure that includes the mold release layer, the antistatic layer, and the substrate such that the surface on the mold release layer side faces a space in the cavity of the mold; and filling the cavity with the curable resin and curing the curable resin in a state of being in contact with the mold release film to form the resin-encapsulation portion that encapsulates the semiconductor element.

As the method for manufacturing the semiconductor package of the present disclosure, a known manufacturing method can be adopted except that the mold release film of the present disclosure is used. Examples of a method for forming the resin-encapsulation portion include a compression molding method and a transfer molding method, and a known compression molding device or transfer molding device can be used as a device used at this time. Manufacturing conditions can also be the same as those in a known method for manufacturing a semiconductor package.

Hereinafter, as representative examples, the compression molding method and the transfer molding method will be described with reference to the drawings, but the method for manufacturing the semiconductor package of the present disclosure is not limited to these drawings. In the following description, a semiconductor package having a so-called MAP-BGA shape is shown as an example of the semiconductor package, but a shape of the semiconductor package is not limited thereto.

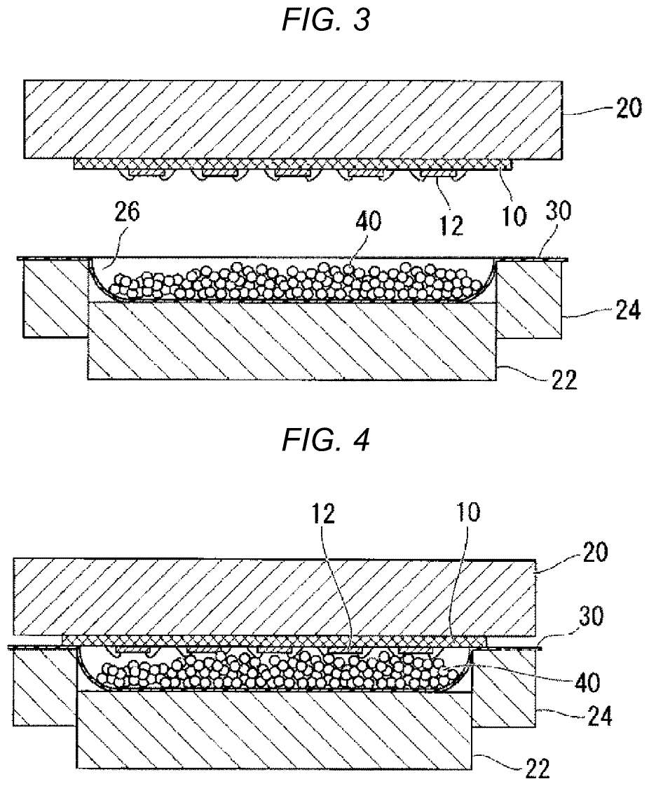

FIG. 3 and FIG. 4 are cross-sectional views schematically illustrating an outline of the compression molding method.

In the compression molding method shown in FIG. 3, a mold is used that includes a fixed upper mold 20, a cavity bottom member 22, and a frame-shaped movable lower mold 24 disposed on a peripheral edge of the cavity bottom member 22. The fixed upper mold 20 is formed with a vacuum vent (not shown) for suctioning a board 10 to the fixed upper mold 20 by suctioning air between the board 10 and the fixed upper mold 20. The cavity bottom member 22 is formed with a vacuum vent (not shown) for suctioning a mold release film 30 to the cavity bottom member 22 by suctioning air between the mold release film 30 and the cavity bottom member 22.

The mold release film 30 is disposed on the movable lower mold 24 so as to cover an upper surface of the cavity bottom member 22. At this time, the mold release film 30 is disposed with a first surface facing upward (direction opposite to the cavity bottom member 22).

The mold release film 30 is fed from an unwinding roll (not shown) and taken up by a winding roll (not shown). The mold release film 30 is stretched by the unwinding roll and the winding roll, and thus is disposed on the movable lower mold 24 in a stretched state.

Separately, vacuum suction is performed through the vacuum vent (not shown) of the cavity bottom member 22, a pressure in a space between the upper surface of the cavity bottom member 22 and the mold release film 30 is reduced, and the mold release film 30 is stretched and deformed, and is vacuum-suctioned to the upper surface of the cavity bottom member 22. Further, the frame-shaped movable lower mold 24 disposed on the peripheral edge of the cavity bottom member 22 is tightened, and the mold release film 30 is stretched from all directions to be in a tensioned state.

The mold release film 30 may not necessarily adhere to a cavity surface depending on a strength and a thickness of the mold release film 30 in a high-temperature environment and a shape of a concave portion formed by the upper surface of the cavity bottom member 22 and an inner side surface of the movable lower mold 24. In a vacuum suction stage, as shown in FIG. 3, a small gap may remain between the mold release film 30 and the cavity surface.

As shown in FIG. 3, an appropriate amount of a curable resin 40 is loaded onto the mold release film 30 in a cavity 26 by an applicator (not shown).

Separately, vacuum suction is performed through the vacuum vent (not shown) of the fixed upper mold 20, and the board 10 on which a plurality of semiconductor chips 12 are mounted is vacuum-suctioned to a lower surface of the fixed upper mold 20.

As the curable resin 40, various curable resins used for manufacturing a semiconductor package may be used. A thermosetting resin such as an epoxy resin or a silicone resin is preferred, and an epoxy resin is particularly preferred.

Next, as shown in FIG. 4, in a state where the curable resin 40 is loaded onto the mold release film 30 in the cavity 26, the cavity bottom member 22 and the movable lower mold 24 are raised and clamped with the fixed upper mold 20.

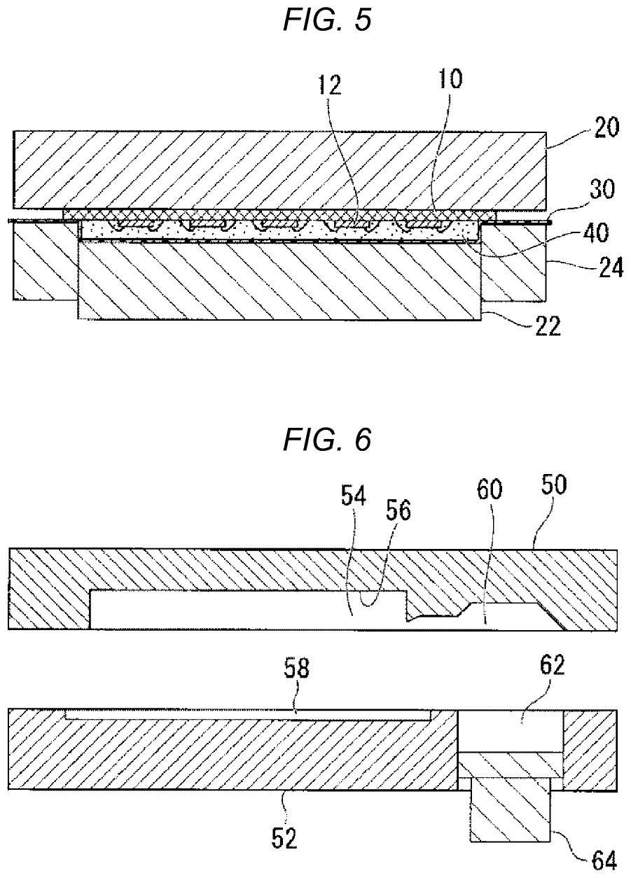

Next, as shown in FIG. 5, only the cavity bottom member 22 is raised and the mold is heated to cure the curable resin 40, thereby encapsulating the semiconductor chip 12.

The curable resin 40 filled in the cavity 26 is further pushed into the cavity surface by a pressure when the cavity bottom member 22 is raised. As a result, the mold release film 30 is stretched and deformed to adhere to the cavity surface. Therefore, a resin-encapsulation portion having a shape corresponding to a shape of the cavity 26 is formed. At this time, unevenness of the first surface of the mold release film 30 is transferred to a surface of the resin-encapsulation portion.

Then, the fixed upper mold 20, the cavity bottom member 22, and the movable lower mold 24 are opened, and a collectively encapsulated body is taken out.

The collectively encapsulated body is released, a used portion of the mold release film 30 is fed to the winding roll (not shown), and an unused portion of the mold release film 30 is fed from the unwinding roll (not shown).

The board 10 and the resin-encapsulation portion of the collectively encapsulated body taken out from the mold are cut (singulated) such that the plurality of semiconductor chips 12 are separated, thereby obtaining singulated encapsulated bodies each including the board 10, at least one semiconductor chip 12, and the resin-encapsulation portion for encapsulating the semiconductor chip 12. The singulation can be performed by a known method, and examples thereof include a dicing method.

Any information is printed by laser marking on an upper surface (surface in contact with the first surface of the mold release film 30) of the resin-encapsulation portion of the obtained singulated encapsulated body to obtain a semiconductor package.

The semiconductor package manufactured using the mold release film of the present disclosure has excellent visibility of characters when the characters are printed by laser marking.

FIG. 6 to FIG. 11 are cross-sectional views schematically illustrating an outline of the transfer molding method.

In the transfer molding method shown in FIG. 6, a mold including an upper mold 50 and a lower mold 52 is used. The upper mold 50 is formed with a cavity 54 having a shape corresponding to a shape of a resin-encapsulation portion 14, and a concave resin introduction portion 60 that guides the curable resin 40 to the cavity 54. The lower mold 52 is formed with a board installation portion 58 for installing the board 10 on which the semiconductor chips 12 are mounted, and a resin placement portion 62 for placing the curable resin 40. A plunger 64 that pushes the curable resin 40 to the resin introduction portion 60 of the upper mold 50 is installed in the resin placement portion 62.

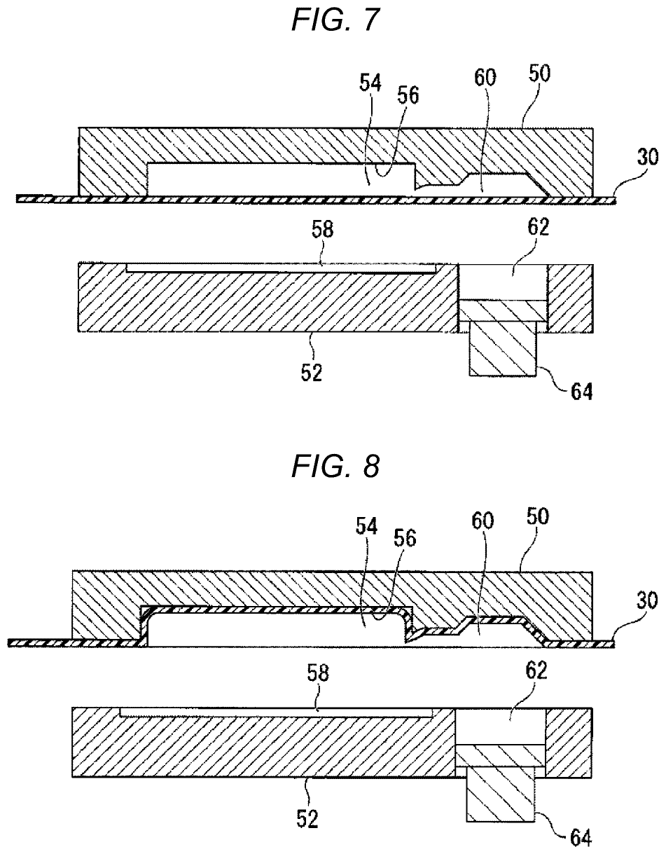

As shown in FIG. 7, the mold release film 30 is disposed so as to cover the cavity 54 of the upper mold 50. The mold release film 30 is preferably disposed so as to entirely cover the cavity 54 and the resin introduction portion 60. The mold release film 30 is stretched by an unwinding roll (not shown) and a winding roll (not shown), and thus is disposed so as to cover the cavity 54 of the upper mold 50 in a stretched state.

Then, as shown in FIG. 8, vacuum suction is performed through a groove (not shown) formed outside the cavity 54 of the upper mold 50, a pressure in each of a space between the mold release film 30 and a cavity surface 56 and a space between the mold release film 30 and an inner wall of the resin introduction portion 60 is reduced, the mold release film 30 is stretched and deformed, and is vacuum-suctioned to the cavity surface 56 of the upper mold 50.

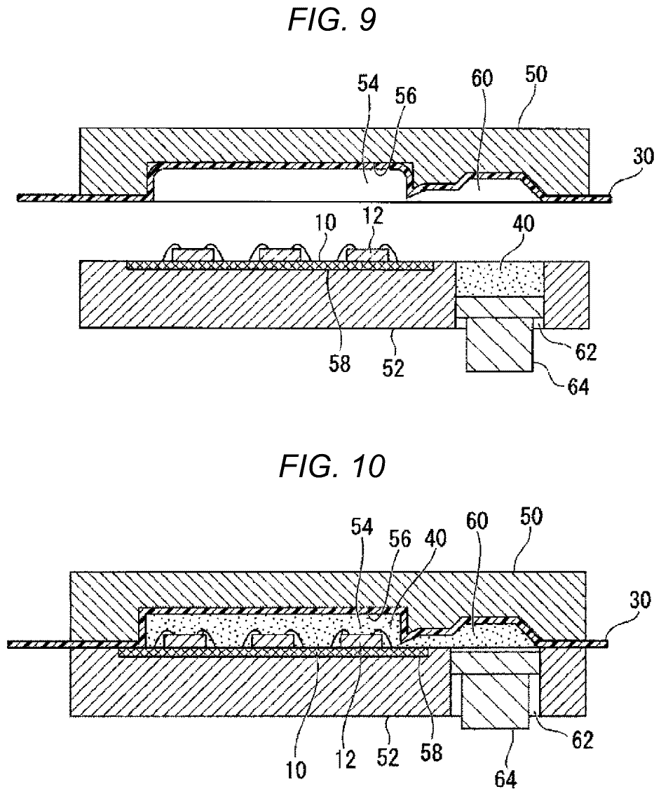

Next, as shown in FIG. 9, the board 10 on which the plurality of semiconductor chips 12 are mounted is installed on the board installation portion 58, the upper mold 50 and the lower mold 52 are clamped, and the plurality of semiconductor chips 12 are arranged at predetermined positions in the cavity 54. In addition, the curable resin 40 is placed in advance on the plunger 64 of the resin placement portion 62. Examples of the curable resin 40 include the same resins as those shown in the compression molding method.

Then, as shown in FIG. 10, the plunger 64 of the lower mold 52 is pushed up to fill the cavity 54 with the curable resin 40 through the resin introduction portion 60. Next, the mold is heated to cure the curable resin 40, thereby forming the resin-encapsulation portion 14 that encapsulates the plurality of semiconductor chips 12.

When the cavity 54 is filled with the curable resin 40, the mold release film 30 is further pushed toward a cavity surface 56 side by a resin pressure, and is stretched and deformed to adhere to the cavity surface 56. Therefore, the resin-encapsulation portion 14 having a shape corresponding to the shape of the cavity 54 is formed.

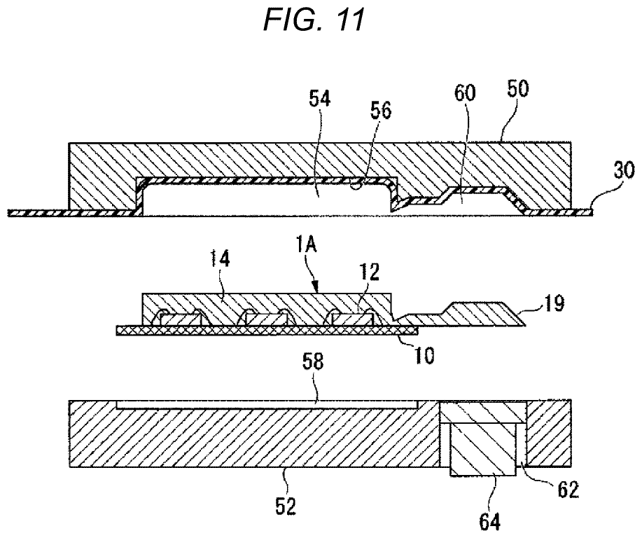

As shown in FIG. 11, a collectively encapsulated body 1A is taken out from the mold. At this time, a cured product 19 obtained by curing the curable resin 40 in the resin introduction portion 60 is taken out from the mold together with the collectively encapsulated body 1A in a state of adhering to the resin-encapsulation portion 14 of the collectively encapsulated body 1A. Therefore, the cured product 19 adhering to the collectively encapsulated body 1A taken out is removed to obtain the collectively encapsulated body 1A.

The board 10 and the resin-encapsulation portion 14 of the obtained collectively encapsulated body 1A are cut (singulated) such that the semiconductor chips 12 are separated, thereby obtaining singulated encapsulated bodies each including the board 10, at least one semiconductor chip 12, and the resin-encapsulation portion encapsulating the semiconductor chip 12. Subsequent steps are the same as those in the compression molding method. In the method for manufacturing the semiconductor package using the mold release film of the present disclosure, a surface of the semiconductor package having excellent laser marking visibility can be formed.

### <Semiconductor Package>

The semiconductor package manufactured by the method for manufacturing the semiconductor package of the present disclosure using the mold release film of the present disclosure may be one manufactured through collective encapsulation and singulation, and examples thereof include a semiconductor package in which an encapsulating method is a moldied array packaging (MAP) method or a wafer level packaging (WL) method.

The semiconductor package manufactured using the mold release film of the present disclosure has a surface with excellent laser marking visibility.

### EXAMPLES

Hereinafter, the present invention will be described in detail with reference to Examples and Comparative Examples, but the present invention is not limited to these Examples.

Among Examples 1 to 27, Examples 1 to 13 and 23 to 27 are inventive examples, and Examples 14 to 22 are comparative examples.

An evaluation method and materials used in each example are shown below.

### [Evaluation Method]

### (Thickness)

An average thickness (μm) of a substrate was measured in accordance with ISO 4591:1992 (JIS K71 30:1999, B1 method, a method for measuring a thickness of a sample taken from a plastic film or sheet by a mass method).

An average thickness (μm) of each of an antistatic layer and a mold release layer was determined by removing each layer from a mold release film using methyl ethyl ketone, measuring a mass before and after the removal, and using a reduced mass and a density of each layer.

### (Arithmetic Average Height Sa)

An arithmetic average height Sa of each of both surfaces of the substrate and a first surface (surface in contact with a curable resin) of the mold release film was measured based on JIS B0601: 2013 (ISO 4287: 1997, Amd. 1: 2009). A laser microscope (LEXT OLS 4000) manufactured by Olympus Corporation was used for the measurement, and an environmental temperature was set to 23° C. to 25° C. A measurement sample was attached to a metal board to eliminate an influence of a large tilt of the measurement sample itself. Main setting conditions in the laser microscope were as follows.

Objective lens: MPLAPON50LEXT (magnification: 50×, numerical aperture: 0.95, immersion type: air, mechanical lens barrel length: ∞, cover glass thickness: 0, field of view: FN18)
Optical zoom magnification: 1×
Scanning mode: XYZ high precision
Captured image size [number of pixels]: 259 μm horizontal×259 μm vertical [1024×1024]
DIC: off
Multilayer: off
Laser intensity: 100
Offset: 0
Confocal level: 0
Beam diameter aperture: off
Image average: one time
Noise reduction: on
Luminance unevenness correction: on
Optical noise filter: on
Cutoff: none (none of λc, λs, and λf)
Filter: Gaussian filter
Noise removal: pre-measurement processing
Tilt correction: not performed

### (Surface Angle Distribution)

A surface shape of the first surface of the mold release film was measured using a laser microscope (LEXT OLS 4000) manufactured by Olympus Corporation in accordance with ISO-25178-2: 2012 under the same conditions as in the measurement of the arithmetic average height Sa. Measurement points were changed and a total of 12 measurements were performed.

For data of an X coordinate, a Y coordinate, and a Z coordinate (height) at each point obtained in increments of 0.25 μm for both the X coordinate and the Y coordinate, a normal vector of unevenness at each point was determined using a MATLAB (registered trademark) R2022b surfnorm function. An angle (θ) formed by the normal vector of the unevenness at each point and a normal line of a main surface of the mold release film was determined, and a histogram was generated in increments of 0.1° to determine a surface angle distribution. In the surface angle distribution, an area ratio of a range of the angle (θ) of 10° to 35° to a total area of a total angle of 0° to 90° was determined as an existence fraction (Φ) in a range of 100 to 350.

### (Surface Resistivity)

A surface resistivity (Ω/□) of the first surface (surface in contact with the curable resin) of the mold release film was measured in accordance with IEC 60093: double ring electrode method. The measurement was performed using an ultra-high resistance meter R8340 (manufactured by Advantec) as a measurement device and a resistivity chamber 12704A as an electrode at an applied voltage of 500 V for an application time of 1 minute.

### (Releasability)

An aluminum foil (JIS H4000: 2006, AlN30P) of 13 cm×13 cm×100 μm thick was stacked on a first stainless steel plate of 13 cm×13 cm. A polyimide film (Upilex 125S, manufactured by Ube Industries, Ltd.) having a thickness of 125 μm and having an area of 8 cm×10 cm hollowed out from 10 cm×12 cm was stacked as a spacer on the aluminum foil. Further, an appropriate amount of an epoxy resin for semiconductor encapsulation (SUMIKON EME G770H type F ver. GR (manufactured by Sumitomo Bakelite Co., Ltd.)) was spread as a curable resin on the hollowed-out portion of the polyimide film. A mold release film cut into a size of 13 cm×13 cm was de-electrified in advance, and then placed on the polyimide film such that the first surface was in contact with the curable resin. Finally, a second stainless steel plate of 13 cm×13 cm was stacked.

A sample produced by the above procedure was pressed by a pressing machine at a temperature of 180° C. and a pressure of 1 MPa for 3 minutes. After being taken out from the pressing machine, the entire sample was placed on a hot plate at 180° C., the second stainless steel plate was removed, and then the mold release film was peeled off by hand over 5 seconds. Evaluation criteria for peelability are as follows.

A (good): peeled off easily.

B (poor): the entire surface could not be peeled off.

### (Chargeability)

For the sample whose releasability was evaluated as A, a static voltage of the first surface of the mold release film was measured immediately after peeling. A surface electrometer MP-520-1 (manufactured by Midori Anzen Co., Ltd.) was used as a device for measuring the static voltage, and a distance between the mold release film and a measurement terminal was fixed to 3 cm. A measurement value was determined by rounding off a digit of 1 V (upper limit of the measurement of the device was 2,000 V). Evaluation criteria for chargeability are as follows.

A (good): |0 to 30| V

B (acceptable): more than |30| V and |50| V or less

C (poor): more than |50| V

### (Adhesive Residue)

For the sample whose releasability was evaluated as A, after the peeling, a surface of a cured product of the cured resin was observed with an optical microscope (magnification of 100×) whether there was a transfer product derived from the mold release film. Evaluation criteria for adhesive residue are as follows.

A (good): no transfer product was observed on the surface of the cured product.

B (poor): transfer product was observed on the surface of the cured product.

### (Laser Marking Visibility Evaluation)

### <Production of Encapsulated Body>

An encapsulated body used for a laser marking visibility evaluation was produced by the following procedure using the film of each example as a mold release film, an epoxy resin for semiconductor encapsulation (SUMIKON EME G770H type F ver. GR (manufactured by Sumitomo Bakelite Co., Ltd.)) as a curable resin, and a transfer molding device (G-LINE Manual System, manufactured by APIC YAMADA Co., Ltd.) as a encapsulating device.

A mold temperature was set to 175° C., and a lead frame made of copper having a size of 70 mm×230 mm and a mold release film roll having a width of 190 mm were set in a roll-to-roll setup. After the lead frame was disposed on a lower mold, the mold release film was vacuum-suctioned to an upper mold, and the mold was clamped, and then the curable resin was injected. After a pressure was applied for 5 minutes, the mold was opened, and an encapsulated package was taken out.

For the film whose releasability was evaluated as B described above, when the mold was opened, the cured product of the encapsulating resin and a part of the mold release film were not released, causing an abnormal separation, and for the film whose releasability was evaluated as A, no abnormal separation occurred.

### <Laser Marking>

A discoloration pattern (printed characters) was formed on a laser marking layer using a laser marker (product name: MD-X1000) having a wavelength of 1064 nm manufactured by Keyence Corporation. As laser marking conditions, the number of times of printing was 1, a scanning speed was 1000 mm/s, a frequency was 100 kHlz, a laser power was 20%, a printing thickness was 0.3 mm, the number of lines was 5, and a spot variation was −20. The printed characters were 10 alphabet characters (ABCDEFGHIJ), printed with a height of 2.0 mm and a width of 1.5 mm of one character, and a character interval of 0.5 mm. A laser marking portion (printed characters) thus produced was evaluated for visibility.

### <Visibility of Marking Portion>

Fifty packages on which 10 alphabets (ABCDEFGHIJ) were printed by laser marking were evaluated, and a reading test was performed on all the packages, that is, 500 characters. Evaluation criteria for the visibility are as follows.

A (good): all 500 characters were readable, and a reading rate was 100%.

B (acceptable): one or two characters could not be read, and the reading rate was 99.8% or 99.6%.

C (poor): three or more characters could not be read, and the reading rate was 99.4% or less.

The term “readable” refers to a reading score of 80 to 99, and a reading score of less than 80 is considered unreadable. In an evaluation for the reading score, a high-speed and high-capacity flexible image processing system manufactured by KEYENCE was used. A device used for the evaluation is not limited as long as the evaluation can be performed under conditions that an incident angle of a red LED is set to 20° to 70° with respect to a horizontal plane of a surface of a package and a detection camera is perpendicular to the horizontal plane of the package. The following basic conditions reproduced conditions adopted in representative laser visibility evaluation devices, for example, ICOS component inspection devices CI-9×50 and CI-G10 manufactured by KLA.

### Measurement Equipment

High-capacity controller: XG-X2700
16× 21 megapixel monochrome camera: CA-H2100M
4/3 inch 50 mm lens: CA-LHE50 (focal depth±2.5 mm)
Red illumination dome Φ 152: CA-DDR15
Application: XG-X2000 Series Ver. 2.2

### Measurement Conditions

Measurement area per data: 6.48 μm×6.48 μm (42 μm²) Distance between sample and lens: a position indicating a maximum luminance was determined while monitoring a luminance of a non-marking portion at a temporary distance of 170 mm, and the distance was shortened by 1.0 mm from the position.

A red LED illumination dome was installed such that an incident angle to a surface of a package was 20° to 70°, and a camera was set in a direction perpendicular to the surface of the package. A camera sensitivity was 3.0, a shutter speed was 20 msec, an illumination brightness was 511, and a gray level was 14. A lens aperture was 2.8.

### Reading Score

A visibility reading score was determined by OCR2 in the application XG-X2000 Series Ver. 2.2. In advance, 10 characters A, B, C, D, E, F, G, H, I, and J (character size: 2.0 mm vertical, 1.5 mm horizontal, 0.5 mm character interval) of good products with no visibility problems were registered in a quadrangular region in which the characters were included without excess or deficiency, and then characters laser-marked on each package sample were read.

A reading score (reading score of 99 is the best) was determined by comparing the registered characters of the good products with the characters on the surface of the package.

### (Luminance of Non-Marking Portion)

An encapsulated body was produced in the same manner as in the laser marking visibility evaluation, and a luminance of the encapsulated body was measured using the high-speed and high-capacity flexible image processing system manufactured by KEYENCE. The measurement was performed under the same conditions as in the visibility evaluation except that a measurement area was 1.5 mm×16 mm=24 mm². The luminance is represented by a numerical value in a range of 0 to 255, where 0 corresponds to a dark side and 255 corresponds to a bright side. The measurement area is divided into sections of 6.48 μm×6.48 μm per one section, and the luminance is measured for each section. Therefore, the luminance is determined as a luminance distribution in the measurement area. An average value was determined based on the obtained luminance distributions in the measurement area and used as an average luminance. An average luminance of the laser marking portion was 160.

### [Materials Used]

### (Substrate)

ETFE film: an ETFE film was produced using the following ETFE (1) or ETFE (2). A method for producing the ETFE film is described in each example.

ETFE (1): Fluon (registered trademark) ETFE C-88AXP (manufactured by AGC Inc.)

ETFE (2): Fluon (registered trademark) LM-ETFE LM-720AP (manufactured by AGC Inc.)

PMP (polymethylpentene) film: X-88BMT4 manufactured by Mitsui Chemicals Tohcello, Inc., double-sided embossed type with a thickness of 50 μm (arithmetic average heights Sa of surfaces are 2.5 μm and 1.4 μm, respectively) PET (polyethylene terephthalate) film: S-38 (LS) manufactured by Unitika Ltd., a biaxially stretched polyethylene terephthalate film having a thickness of 38 μm was used, and a so-called sand mat treatment in which sand was sprayed was performed to form unevenness on one surface of the film. Arithmetic average heights Sa of surfaces were 1.6 μm and 0.1 μm, respectively.

SPS (syndiotactic polystyrene) film: XAREC (registered trademark) 142ZE (manufactured by Idemitsu Kosan Co., Ltd.) was fed to an extruder equipped with a T-die, taken up between mirror-finished metal rolls, and simultaneously stretched in a flow direction of a film and in a direction orthogonal to the flow direction to form a film having a thickness of 50 μm. A temperature of the extruder and the T-die was 270° C., a temperature of a cooling rolls was 100° C., a stretching temperature was 115° C., a stretching ratio was 3.3 times in both the flow direction and the direction orthogonal to the flow direction, and a stretching speed was 500%/min. After a stretching step, a heat treatment was performed at 215° C. Further, in order to form unevenness on one surface of the film, a so-called sand mat treatment in which sand was sprayed was performed. Arithmetic average heights Sa of surfaces were 1.9 μm and 0.1 μm, respectively.

In each film, a surface having a high arithmetic average height Sa was subjected to a corona treatment such that a wet tension based on IS08296: 1987 (JIS K6768: 1999) was 40 mN/m or more. When arithmetic average heights Sa of both surfaces were the same, the corona treatment was performed on one surface.

### (Antistatic Layer Liquid)

10 parts by mass of a polythiophene-based conductive polymer dispersion containing an acrylic resin (Aracoat (registered trademark) AS601D (solid content: 4 mass %, manufactured by Arakawa Chemical Industries, Ltd.)) and 1 part by mass of a polyfunctional aziridine compound curing agent (Aracoat (registered trademark) CL910 (solid content: 10 mass %, manufactured by Arakawa Chemical Industries, Ltd.)) were mixed. The obtained mixture was diluted with a mixed solvent of isopropanol/toluene/water=50/40/10 (mass ratio) to obtain a solid content concentration of each example, thereby obtaining an antistatic layer liquid. A surface resistivity of an antistatic layer itself after the formation of the antistatic layer to be described later was 7×10⁷Ω/□.

### (Mold Release Layer Liquid)

Mold release layer liquid (1): 100 parts by mass of Nissetsu (registered trademark) KP2562 (manufactured by Nippon Carbide Industries Co., Inc., solid content: 35 mass %, hydroxy group-containing (meth)acrylic polymer (hydroxyl value: 70 mgKOH/g, crosslinking functional group equivalent: 801 g/mol)), 6 parts by mass of Nissetsu (registered trademark) CK157 (manufactured by Nippon Carbide Industries Co., Inc., solid content: 100 mass %, trifunctional isocyanate compound (isocyanurate-type hexamenthylene diisocyanate)), and 21 parts by mass of Nissetsu (registered trademark) CK-939 (manufactured by Nippon Carbide Industries Co., Inc., solid content: 0.5 mass %, acetylacetone solution of dioctyltin dilaurate) were mixed. The obtained mixture was diluted with ethyl acetate to obtain a solid content concentration of each example, thereby obtaining a mold release layer liquid.

Mold release layer liquid (2-1): 10 parts by mass of TAFTIC FH-S005 (trade name, manufactured by Toyobo Co., Ltd., acrylic particles, average particle diameter: 5 m) as resin particles were further added to and mixed with the mixture of the mold release layer liquid (1) before dilution with a solvent of ethyl acetate, and the mixture was diluted with ethyl acetate to obtain a solid content concentration of 26 mass %, thereby obtaining a mold release layer liquid. A content ratio of acrylic particles contained in a mold release layer formed by the mold release layer liquid corresponds to 16.9 vol %.

Mold release layer liquid (2-2): a mold release layer liquid was obtained by the same procedure as that of the mold release layer liquid (2-1) except that an amount of TAFTIC FH-S005 was changed to 2 parts by mass. A content ratio of acrylic particles contained in a mold release layer formed by the mold release layer liquid corresponds to 3.9 vol %.

Mold release layer liquid (3-1): 10 parts by mass of SUNSPHERE H-31 (manufactured by AGC Si-Tech Co., Ltd., silica particles, average particle diameter: 3 μm) as resin particles were further added to and mixed with the mixture of the mold release layer liquid (1) before dilution with a solvent of ethyl acetate, and the mixture was diluted with ethyl acetate to obtain a solid content concentration of 20 mass %, thereby obtaining a mold release layer liquid. A content ratio of silica particles contained in a mold release layer formed by the mold release layer liquid corresponds to 11.9 vol %.

Mold release layer liquid (3-2): a mold release layer liquid was obtained by the same procedure as that of the mold release layer liquid (3-1) except that an amount of SUNSPHERE H-31 (trade name, manufactured by AGC Si-Tech Co., Ltd., silica particles, average particle diameter: 3 μm) was changed to 3.5 parts by mass. A content ratio of silica particles contained in a mold release layer formed by the mold release layer liquid corresponds to 4.5 vol %.

### Example 1

ETFE (1) was fed into an extruder and melt-extruded at 320° C. by an extruder in which a lip opening was adjusted such that a thickness of a film was 50 μm, and the film was taken up at an adjusted film forming speed using two original mold rolls in which unevenness was formed on a surface, thereby manufacturing an ETFE film having an uneven structure on both surfaces. Arithmetic average heights Sa of both surfaces were 2.5 μm and 2.5 μm, respectively. Further, one surface of the ETFE film was subjected to a corona treatment. An antistatic layer liquid having a solid content concentration of 4.0 mass % was applied to the corona-treated surface of the ETFE film using a gravure coater and dried to form an antistatic layer having a thickness of 0.25 μm. The coating was performed by a direct gravure method using a roll with grating 150 # of Φ 100 mm×250 mm width and a depth of 40 μm as a gravure plate, and a coating speed was 4 m/min. The drying was performed at 100° C. for 1 minute through a roll-support drying oven with an air volume of 15 m/sec.

A mold release layer liquid (1) having a solid content concentration of 13 mass % was applied onto the antistatic layer with a gravure coater and dried to form a mold release layer having a thickness of 1.0 μm. The coating was performed by a direct gravure method using a roll with grating 150 # of Φ100 mm×250 mm width and a depth of 40 μm as a gravure plate. The drying was performed at 100° C. for 1 minute through a roll-support drying oven with an air volume of 19 m/sec. Next, curing was performed at 40° C. for 120 hours to obtain a mold release film.

### Example 2

In the same manner as in Example 1, except that one of original mold rolls was changed to adjust a film forming speed, an ETFE film having arithmetic average heights Sa of both surfaces of 1.9 μm and 1.3 μm respectively was manufactured, a corona treatment was performed on a surface having a high arithmetic average height Sa, and an antistatic layer was formed using an antistatic layer liquid having a solid content concentration of 3.2 mass % to obtain a mold release film.

### Example 3

In the same manner as in Example 2, except that ETFE (2) was used as a resin, a film forming speed was adjusted, an ETFE film having a thickness of 60 μm and arithmetic average heights Sa of both surfaces of 2.0 μm and 1.4 μm respectively was manufactured, a corona treatment was performed on a surface having a high arithmetic average height Sa of the film, an antistatic layer was formed using an antistatic layer liquid having a solid content concentration of 4.0 mass %, and then a mold release layer was formed using a mold release layer liquid (1) having a solid content concentration of 16 mass % to obtain a mold release film.

### Example 4

In the same manner as in Example 2, except that a film forming speed was adjusted, an ETFE film having arithmetic average heights Sa of both surfaces of 1.7 μm and 1.7 μm respectively was manufactured, an antistatic layer was formed on a corona-treated surface using an antistatic layer liquid having a solid content concentration of 2.4 mass %, and then a mold release layer was formed using a mold release layer liquid (1) having a solid content concentration of 29 mass % to obtain a mold release film.

### Example 5

In the same manner as in Example 1, except that one of original mold rolls was not used, a film forming speed was adjusted, an ETFE film having arithmetic average heights Sa of both surfaces of 1.6 μm and less than 0.05 μm respectively was manufactured, a corona treatment was performed on a surface having a high arithmetic average height Sa, and an antistatic layer and a mold release layer were further formed to obtain a mold release film.

### Example 6

In the same manner as in Example 3, except that an antistatic layer liquid having a solid content concentration of 6.9 mass % and a mold release layer liquid (1) having a solid content concentration of 10 mass % were used to obtain a mold release film.

### Example 7

In the same manner as in Example 6, except that a mold release layer liquid (1) having a solid content concentration of 2.6 mass % was used to obtain a mold release film.

### Example 8

In the same manner as in Example 3, except that a film forming speed was adjusted, an ETFE film having a film thickness of 70 μm and having arithmetic average heights Sa of both surfaces of 1.4 μm and 1.0 μm respectively was manufactured, a corona treatment was performed on a surface having a high arithmetic average height Sa, an antistatic layer was formed using an antistatic layer liquid having a solid content concentration of 5.0 mass %, and then a mold release layer was formed using a mold release layer liquid (1) having a solid content concentration of 2.5 mass % to obtain a mold release film.

### Example 9

In the same manner as in Example 8, except that a mold release layer liquid (1) having a solid content concentration of 5.6 mass % was used to obtain a mold release film.

### Example 10

In the same manner as in Example 8, except that a mold release layer liquid (1) having a solid content concentration of 7.2 mass % was used to obtain a mold release film.

### Example 11

In the same manner as in Example 1, except that a PMP film was used instead of the ETFE film to obtain a mold release film.

### Example 12

In the same manner as in Example 1, except that a PET film was used instead of the ETFE film, and a mold release layer liquid (1) having a solid content concentration of 7.8 mass % was used to obtain a mold release film.

### Example 13

In the same manner as in Example 12, except that an SPS film was used instead of the ETFE film to obtain a mold release film.

### Example 14

In the same manner as in Example 8, except that an antistatic layer liquid having a solid content concentration of 4.2 mass % and a mold release layer liquid (1) having a solid content concentration of 1.3 mass % were used to obtain a mold release film.

### Example 15

In the same manner as in Example 1, except that a film forming speed was adjusted, an ETFE film having arithmetic average heights Sa of both surfaces of 1.6 μm and 1.6 μm respectively was manufactured, and a mold release layer liquid (1) having a solid content concentration of 31 mass % was used to obtain a mold release film.

### Example 16

In the same manner as in Example 3, except that an antistatic layer liquid having a solid content concentration of 6.9 mass % and a mold release layer liquid (1) having a solid content concentration of 36 mass % were used to obtain a mold release film.

### Example 17

In the same manner as in Example 8, except that a mold release layer liquid (1) having a solid content concentration of 31 mass % was used to obtain a mold release film.

### Example 18

In the same manner as in Example 5, except that an antistatic layer was formed using an antistatic layer liquid having a solid content concentration of 1.6 mass %, and then a mold release layer was formed using a mold release layer liquid (1) having a solid content concentration of 20 mass % to obtain a mold release film.

### Example 19

In the same manner as in Example 8, except that a mold release film was obtained without forming an antistatic layer and a mold release layer.

### Example 20

In the same manner as in Example 1, except that a mold release film was obtained without forming a mold release layer.

### Example 21

In the same manner as in Example 3, except that a mold release film was obtained without forming a mold release layer.

### Example 22

In the same manner as in Example 8, except that a mold release film was obtained without forming a mold release layer.

### Example 23

In the same manner as in Example 5, except that a mold release layer liquid (2-1) was used instead of the mold release layer liquid (1), a corona treatment was performed on a surface having a low arithmetic average height Sa, and an antistatic layer and a mold release layer were further formed to obtain a mold release film.

### Example 24

In the same manner as in Example 1, except that a mold release layer liquid (2-1) was used instead of the mold release layer liquid (1) to obtain a mold release film.

### Example 25

In the same manner as in Example 1, except that a mold release layer liquid (2-2) was used instead of the mold release layer liquid (1) to obtain a mold release film.

### Example 26

In the same manner as in Example 1, except that a mold release layer liquid (3-1) was used instead of the mold release layer liquid (1) to obtain a mold release film.

### Example 27

In the same manner as in Example 1, except that a mold release layer liquid (3-2) was used instead of the mold release layer liquid (1) to obtain a mold release film.

The above evaluations were performed for the mold release films of Examples 1 to 27, encapsulated bodies produced using these mold release films, and encapsulated bodies subjected to laser marking. Results are shown in Tables 1 to 3.

TABLE 1

| | | 1 | 2 | 3 | 4 | 5 | 6 | 7 | 8 | 9 | 10 |
|---|---|---|---|---|---|---|---|---|---|---|---|
| Substrate | Resin | ETFE 1 | ETFE 1 | ETFE 2 | ETFE 1 | ETFE 1 | ETFE 2 | ETFE 2 | ETFE 2 | ETFE 2 | ETFE 2 |
| | Average | 50 | 50 | 60 | 50 | 50 | 60 | 60 | 70 | 70 | 70 |
| | thickness | | | | | | | | | | |
| | (μm) | | | | | | | | | | |
| | Sa on first | 2.5 | 1.9 | 2.0 | 1.7 | 1.6 | 2.0 | 2.0 | 1.4 | 1.4 | 1.4 |
| | surface side | | | | | | | | | | |
| | (μm) | | | | | | | | | | |
| | Sa on second | 2.5 | 1.3 | 1.4 | 1.7 | <0.05 | 1.4 | 1.4 | 1.0 | 1.0 | 1.0 |
| | surface side | | | | | | | | | | |
| | (μm) | | | | | | | | | | |
| Average thickness of | | 0.25 | 0.20 | 0.25 | 0.15 | 0.25 | 0.43 | 0.43 | 0.31 | 0.31 | 0.31 |
| antistatic layer (μm) | | | | | | | | | | | |
| Mold | Average | 1.0 | 1.0 | 1.2 | 2.2 | 1.0 | 0.8 | 0.2 | 0.2 | 0.4 | 0.6 |
| release | thickness | | | | | | | | | | |
| layer | (μm) | | | | | | | | | | |
| | Presence or | absent | absent | absent | absent | absent | absent | absent | absent | absent | absent |
| | absence of | | | | | | | | | | |
| | particles | | | | | | | | | | |
| Mold | Sa of first | 2.1 | 1.3 | 1.4 | 1.3 | 1.2 | 1.4 | 1.7 | 1.2 | 1.1 | 1.1 |
| release | surface (μm) | | | | | | | | | | |
| film | Releasability | A | A | A | A | A | A | A | A | A | A |
| | Surface | 1.4 × | 3.6 × | 3.9 × | 3.3 × | 1.4 × | 2.3 × | 4.2 × | 1.2 × | 1.4 × | 9.1 × |
| | resistivity of | 10¹⁰ | 10⁹ | 10⁹ | 10⁹ | 10⁹ | 10⁸ | 10⁸ | 10⁸ | 10⁸ | 10⁷ |
| | first surface | | | | | | | | | | |
| | (Ω/□) | | | | | | | | | | |
| | Static voltage | 24 | 11 | 10 | 12 | 10 | 10 | 8 | 10 | 12 | 11 |
| | of first surface | | | | | | | | | | |
| | (V) | | | | | | | | | | |
| | Evaluation of | A | A | A | A | A | A | A | A | A | A |
| | static voltage | | | | | | | | | | |
| | Existence | 0.48 | 0.16 | 0.26 | 0.14 | 0.38 | 0.17 | 0.37 | 0.65 | 0.53 | 0.41 |
| | fraction (Φ) | | | | | | | | | | |
| | (10° to 35°) | | | | | | | | | | |
| Encapsulated | Luminance of | 84 | 63 | 73 | 58 | 79 | 65 | 68 | 98 | 92 | 81 |
| body | non-marking | | | | | | | | | | |
| | portion | | | | | | | | | | |
| | Laser marking | A | A | A | B | A | A | A | B | A | A |
| | visibility | | | | | | | | | | |
| | Adhesive | A | A | A | A | A | A | A | A | A | A |
| | residue | | | | | | | | | | |

TABLE 2

| | Example | 11 | 12 | 13 | 14 | 15 | 16 | 17 | 18 |
|---|---|---|---|---|---|---|---|---|---|
| Substrate | Resin | PMP | PET | SPS | ETFE 2 | ETFE 1 | ETFE 2 | ETFE 2 | ETFE 1 |
| | Average thickness | 50 | 38 | 50 | 70 | 50 | 60 | 70 | 50 |
| | (μm) | | | | | | | | |
| | Sa on first surface | 2.5 | 1.6 | 1.9 | 1.4 | 1.6 | 2.0 | 1.4 | 1.6 |
| | side (μm) | | | | | | | | |
| | Sa on second | 1.4 | 0.1 | 0.1 | 1.0 | 1.6 | 1.4 | 1.0 | <0.05 |
| | surface side (μm) | | | | | | | | |
| Average thickness of | | 0.25 | 0.25 | 0.25 | 0.26 | 0.25 | 0.43 | 0.31 | 0.10 |
| antistatic layer (μm) | | | | | | | | | |
| Mold | Average thickness | 1.0 | 0.6 | 0.6 | 0.1 | 2.4 | 2.8 | 2.4 | 1.5 |
| release | (μm) | | | | | | | | |
| layer | Presence or absence | absent | absent | absent | absent | absent | absent | absent | absent |
| | of particles | | | | | | | | |
| Mold | Sa of first surface | 1.5 | 1.3 | 1.5 | 1.2 | 1.2 | 0.6 | 0.7 | 0.06 |
| release | (μm) | | | | | | | | |
| film | Releasability | A | A | A | B | A | A | A | A |
| | Surface resistivity of | 6.8 × | 5.2 × | 7.9 × | 1.1 × | 3.3 × | 8.2 × | 2.5 × | 7.8 × |
| | first surface (Ω/□) | 10⁸ | 10⁸ | 10⁸ | 10⁸ | 10⁹ | 10⁸ | 10⁸ | 10⁸ |
| | Static voltage of first | 12 | 12 | 16 | 10 | 12 | 27 | 24 | 12 |
| | surface (V) | | | | | | | | |
| | Evaluation of static | A | A | A | A | A | A | A | A |
| | voltage | | | | | | | | |
| | Existence fraction | 0.40 | 0.29 | 0.32 | 0.67 | 0.11 | 0.03 | 0.07 | 0.04 |
| | (Φ) (10° to 35°) | | | | | | | | |
| Encapsulated | Luminance of non- | 80 | 67 | 72 | 103 | 54 | 45 | 54 | 47 |
| body | marking portion | | | | | | | | |
| | Laser marking | A | A | A | C | C | C | C | C |
| | visibility | | | | | | | | |
| | Adhesive residue | A | A | A | — | B | B | B | A |

TABLE 3

| | Example | 19 | 20 | 21 | 22 | 23 | 24 | 25 | 26 | 27 |
|---|---|---|---|---|---|---|---|---|---|---|
| Substrate | Resin | ETFE 2 | ETFE 1 | ETFE 2 | ETFE 2 | ETFE 1 | ETFE 1 | ETFE 1 | ETFE 1 | ETFE 1 |
| | Average | 70 | 50 | 60 | 70 | 50 | 50 | 50 | 50 | 50 |
| | thickness (μm) | | | | | | | | | |
| | Sa on first | 1.4 | 2.5 | 2.0 | 1.4 | <0.05 | 2.5 | 2.5 | 2.5 | 2.5 |
| | surface side (μm) | | | | | | | | | |
| | Sa on second | 1.0 | 2.5 | 1.4 | 1.0 | 1.60 | 2.5 | 2.5 | 2.5 | 2.5 |
| | surface side (μm) | | | | | | | | | |
| Average thickness of | | — | 0.25 | 0.25 | 0.31 | 0.25 | 0.25 | 0.25 | 0.25 | 0.25 |
| antistatic layer (μm) | | | | | | | | | | |
| Mold | Average | — | — | — | — | 2.0 | 2.0 | 2.1 | 1.5 | 1.7 |
| release | thickness (μm) | | | | | | | | | |
| layer | Presence or | — | — | — | — | present | present | present | present | present |
| | absence of | | | | | | | | | |
| | particles | | | | | | | | | |
| Mold | Sa of first | 1.3 | 2.4 | 1.7 | 1.2 | 3.1 | 2.7 | 2.6 | 2.0 | 1.9 |
| release | surface (μm) | | | | | | | | | |
| film | Releasability | A | B | B | B | A | A | A | A | A |
| | Surface | 9.9 × | 5.9 × | 2.9 × | 1.1 × | 3.2 × | 1.2 × | 9.7 × | 4.2 × | 1.7 × |
| | resistivity of first | 10¹⁵ | 10⁹ | 10⁹ | 10⁸ | 10¹² | 10¹⁰ | 10⁹ | 10¹⁰ | 10¹⁰ |
| | surface (Ω/∪) | | | | | | | | | |
| | Static voltage of | −1011 | — | — | — | 46 | 25 | 23 | 29 | 25 |
| | first surface (V) | | | | | | | | | |
| | Evaluation of | C | — | — | — | B | A | A | A | A |
| | static voltage | | | | | | | | | |
| | Existence | 0.72 | 0.59 | 0.59 | 0.69 | 0.27 | 0.57 | 0.35 | 0.64 | 0.42 |
| | fraction (Φ) | | | | | | | | | |
| | (10° to 35°) | | | | | | | | | |
| Encapsulated | Luminance of | 114 | 92 | 89 | 107 | 67 | 89 | 75 | 95 | 79 |
| body | non-marking | | | | | | | | | |
| | portion | | | | | | | | | |
| | Laser marking | C | A | A | C | A | A | A | A | A |
| | visibility | | | | | | | | | |
| | Adhesive residue | A | — | — | — | A | A | A | A | A |

As shown in the above results, the mold release films of Examples 1 to 13 and 23 to 27, which included a mold release layer, an antistatic layer, and a substrate, and in which an average thickness of the mold release layer was more than 0.1 μm and an existence fraction (Φ) in a range of 100 to 350 on a surface of a first surface was 0.12 or more, had excellent releasability and antistatic properties. In addition, the encapsulated bodies manufactured using the mold release films of Examples 1 to 13 and 23 to 27 had a surface excellent in laser marking visibility while preventing a luminance abnormality due to a resin flow trace (flow mark) on a surface of a semiconductor package or a scratch on the surface of the package.

As one of characteristics of the visibility, when a difference in an average luminance between a laser marking portion and a non-marking portion is large, a contrast is increased and the visibility is improved. From the above evaluation results, it was found that the average luminance of the non-marking portion is preferably 100 or less, and more preferably 95 or less, from a viewpoint of increasing the contrast. On the other hand, it was found that the average luminance of the non-marking portion is preferably 55 or more, and more preferably 60 or more because a phenomenon in which a luminance is increased on a part of the surface due to the resin flow trace (flow mark) on the surface of the package or the scratch on the surface of the package occurs in the non-marking portion, and a reading rate decreases.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2023-015583) filed on Feb. 3, 2023, the content of which is incorporated herein by reference.

### INDUSTRIAL APPLICABILITY

The mold release film of the present disclosure can form a surface of a semiconductor package that has excellent antistatic properties and releasability from the semiconductor package and has excellent laser marking visibility. A semiconductor package having a surface with excellent laser marking visibility can be manufactured using the mold release film of the present disclosure.

### REFERENCE SIGNS LIST

1A: collectively encapsulated body
10: board
12: semiconductor chip (semiconductor element)
19: cured product
20: fixed upper mold
22: cavity bottom member
24: movable lower mold
26: cavity
30: mold release film
32: unevenness on surface of mold release film
40: curable resin
50: upper mold
52: lower mold
54: cavity
56: cavity surface
58: board installation portion
60: resin introduction portion
62: resin placement portion
64: plunger

1. A mold release film comprising a mold release layer, an antistatic layer, and a substrate in this order, wherein
an average thickness of the mold release layer is more than 0.1 μm, and
when unevenness of a surface of the mold release film on a mold release layer side is measured with a laser microscope and a surface angle distribution of an angle (θ) formed by a normal vector of the unevenness and a normal line of a main surface of the mold release film is determined, an existence fraction (Φ) in a range of 10° to 35° is 0.12 or more.

2. The mold release film according to claim 1, wherein an arithmetic average height Sa of at least one surface of the substrate is 0.9 μm or more.

3. The mold release film according to claim 2, wherein an arithmetic average height Sa of a surface of the substrate on an antistatic layer side is 1.2 μm or more.

4. The mold release film according to claim 1, wherein a content ratio of particles in the mold release layer is 25 vol % or less.

5. The mold release film according to claim 1, wherein the substrate contains a fluororesin.

6. The mold release film according to claim 5, wherein the fluororesin contains an ethylene-tetrafluoroethylene copolymer.

7. The mold release film according to claim 1, wherein the surface of the mold release film on the mold release layer side has a surface resistivity of 1×10⁷Ω/□ to 1×10¹¹Ω/□.

8. The mold release film according to claim 1, which is to be disposed between a curable resin and a surface of a mold in manufacture of a semiconductor package.

9. The mold release film according to claim 8, wherein the surface of the mold release film on the mold release layer side is to be in contact with the curable resin.

10. A method for manufacturing a semiconductor package, the semiconductor package including a semiconductor element and a resin-encapsulation portion that encapsulates the semiconductor element and is formed of a curable resin, the method comprising:
disposing a board including the semiconductor element in a cavity of a mold;
disposing, on a cavity surface of the mold on which the board is not disposed, the mold release film according to claim 1 that includes the mold release layer, the antistatic layer, and the substrate such that the surface on the mold release layer side faces a space in the cavity; and
filling the cavity with the curable resin and curing the curable resin in a state of being in contact with the mold release film to form the resin-encapsulation portion that encapsulates the semiconductor element.
